(19) United States
(12) Patent Application Publication
(10) Pub. No.: US 2023/0123602 A1
(43) Pub. Date: Apr. 20, 2023

(54) SEMICONDUCTOR APPARATUS AND SEMICONDUCTOR DEVICE, AND METHOD OF PRODUCING THE SAME

(71) Applicant: Gesellschaft für Angewandte Mikro- und Optoelektronik mit beschränkter Haftung - AMO GmbH, Aachen (DE)

(72) Inventor: Daniel SCHALL, Aachen (DE)

(21) Appl. No.: 17/796,369

(22) PCT Filed: Dec. 21, 2020
(86) PCT No.: PCT/EP2020/087445

§ 371 Date: Jul. 29, 2022

(30) Foreign Application Priority Data
Jan. 31, 2020 (DE) 102020102534.3

(51) Int. Cl. G02B 6/12; H01L 27/144; G02F 1/035; G02B 6/122; G02B 6/132

(52) U.S. Cl. CPC G02B 6/12004; H01L 27/144; H01L 27/1443; G02F 1/035; G02B 6/1228; G02B 6/132; G02F 2202/101; G02F 2202/104; G02F 2201/063; G02F 2202/36; G02F 2201/066; G02F 2203/10

(57) ABSTRACT

A semiconductor device comprising a wafer with a preferably single-piece semiconductor substrate, in particular silicon substrate, and at least one integrated electronic component extending in and/or on the semiconductor substrate, the wafer having a front-end-of-line and a back-end-of-line lying there above, the front-end-of-line comprising the integrated electronic component or at least one of the integrated electronic components, and a photonic platform fabricated on the side of the wafer facing away from the front-end-of-line, which photonic platform comprises at least one waveguide and at least one electro-optical device, in particular at least one photodetector and/or at least one electro-optical modulator, wherein the electro-optical device or at least one of the electro-optical devices of the photonic platform is connected to the integrated electronic component or at least one of the integrated electronic components of the wafer.

The invention relates to a semiconductor device and a method of manufacturing the same. In addition, the invention relates to a semiconductor apparatus and a method of manufacturing the same.

The exchange of data within and in particular between chips is increasingly reaching capacity limits. The number of possible connections is limited by the available chip area and by technological factors that affect manufacturability. In addition, the bandwidth of electrical connections is limited by electrical losses that increase sharply with frequency. For a wide range of applications, the need for broadband I/O interfaces is above current capacities. Examples of applications are in the field of so-called disaggregated computing, which particularly concerns or includes configurable networking of CPU or GPU and memory, CPU-memory connectivity and IoT networks for autonomous mobility, among others. In the cases mentioned, extreme bandwidth with Gb/s to Tb/s data transfer is often required.

At present, I/O interfaces are essentially implemented electronically. This applies to memory connections, sensor networks (IoT), and essential sectors of data communication. The I/O bandwidth currently technically possible is often not sufficient to achieve the desired transfer rates. Physical relationships that have a fundamentally limiting effect, such as losses and minimal dimensions of electrical contact points, prevent a significant increase in performance. Electrical losses play a significant role, in particular at high frequencies (for example, 10 dB/m in the range around 50 GHz for coaxial conductors), whereas losses in optical fibers in the range of 0.1 dB/km are extremely small in comparison. The change to optical interfaces can solve the problem of bandwidth and range. However, manufacturing low-cost, high-performance components available in very large quantities is a major challenge here. Currently, only silicon technology is capable of doing this, but it comes with only limited photonic functionality. III-V semiconductors are better suited, but not monolithically integrated into Si technology.

In addition to I/O interfaces, other areas of application are conceivable. Optical systems such as filters, spectrometers or neural networks for machine learning could also be realized. Close integration of photonics and electronics could enable novel chip architectures.

Optical interfaces are achieved to some extent for data communication either by heterointegration or bonding techniques of electronic and optical chips. This means that optical and electronic chips are fabricated and subsequently bonded using different technologies. For this purpose, optical circuits based on III-V transition semiconductors are usually bonded to Si wafers with electronic control circuits. The advantage is that each circuit type can be fabricated in its optimal process. However, the significant disadvantage is the high cost and sequential, and therefore time-consuming, manufacturing technique for bonding (each chip must be bonded to the wafer one at a time) and the break of the manufacturing line. After the individual chips are bonded to the wafer, the wafer cannot be further processed as a whole. The wafer is separated in the next step and the chips are finished separately (however, the main part of the manufacturing steps has already been done).

Alternatively, silicon can be used as the starting material and electronic and photonic circuits can be obtained on one chip. In this case, however, the combination of technology for electronic and photonic circuits is fixed because optical and electronic circuits are manufactured in the same layer. The Si electronics and photonics are located on one wafer, side by side. This is known, for example, from the article “Integrating photonics with silicon nanoelectronics for the next generation of systems on a chip,” Nature 556, pages 349-354 (2018), doi: 10.1038/s41586-018-0028-z. The advantage is that significant cost and time savings can be achieved in this combined Si technology compared to the die-attach or bonding strategy with III-V semiconductors. The disadvantage is that the Si photonic devices usually have less good performance compared to III-V transition semiconductors. Another significant disadvantage is that the electronics and photonics technology is fixed, so only certain types of microchips can be reasonably manufactured for technical and economic reasons.

US 2014/0264400 A1 discloses a semiconductor device having integrated circuits. The device includes a plurality of chips having the integrated circuits and being fixed in spaced-apart relation to each other in recesses of a carrier substrate. Planar coats comprising waveguides and photonic devices are deposited on the chips and the substrate surface to provide an optical intra-chip connection for photonic devices of one chip or an optical inter-chip connection for photonic devices of different chips.

The previously known semiconductor devices have proven themselves in principle. However, there is still a need for alternative devices. In particular, there is a need to be able to obtain individual chips with integrated photonics in large quantities with reasonable fabrication effort and thus at reasonable costs.

It is an object of the present invention to provide an alternative semiconductor device in which an integration of electronic circuits and photonic components is realized, and which makes it possible to obtain chips with integrated photonics in high quantities with reasonable effort. Furthermore, it is an object of the invention to obtain a method for manufacturing such a device.

The first-mentioned object is solved by a semiconductor device comprising a wafer with a preferably single-piece semiconductor substrate, in particular a silicon substrate, and at least one integrated electronic component extending in and/or on the semiconductor substrate, the wafer having a front-end-of-line and a back-end-of-line lying there above, wherein the front-end-of-line comprises the integrated electronic component or at least one of the integrated electronic components, and a photonic platform fabricated on the side of the wafer facing away from the front-end-of-line, which photonic platform comprises at least one waveguide and at least one electro-optical device, in particular at least one photodetector and/or at least one electro-optical modulator, wherein the electro-optical device or at least one of the electro-optical devices of the photonic platform is connected to the integrated electronic component or at least one of the integrated electronic components of the wafer.

The second-mentioned object is solved by a method of manufacturing a semiconductor device, comprising the steps:
a wafer having a preferably single-piece semiconductor substrate, in particular a silicon substrate, and at least one integrated electronic component extending in and/or on the semiconductor substrate is provided, the wafer having a front-end-of-line and a back-end-of-line lying there, wherein the front-end-of-line comprises the integrated electronic component or at least one of the integrated electronic components,
a photonic platform is fabricated on the side of the wafer facing away from the front-end-of-line, the photonic platform comprising at least one waveguide and at least one electro-optical device, in particular at least one photodetector and/or at least one electro-optical modulator.

In other words, the basic idea of the present invention is to fabricate directly on the back-end-of-line of a wafer, in particular to build directly thereon, a photonic platform with at least one waveguide and at least one electro-optical device.

In the prior art, a wafer is understood in a manner generally known to be a component or element or device from which a plurality of chips is obtained by wafer dicing, also known as wafer fragmenting (Wafer-Zerkleinern in the German language). The dicing or fragmenting may include, for example, (laser) cutting or sawing or scribing or breaking of the wafer. In English, a single or singular chip is also referred to as a die, or chips in the plural are also referred to as dies or dice. It should be noted that some chips after dicing are also referred to as bare chips or bare dies. “Bare” refers to the fact that the chips have not yet been placed in a package. “Bare” chips without a package are also referred to as chips for short.

If a wafer is viewed in cross-section, its vertical structure can be divided into different sub-regions. The lowest part is the front-end-of-line or FEOL for short, which comprises one or more integrated electronic components. The integrated electronic component(s) may be, for example, transistors and/or capacitors and/or resistors. Above the front-end-of-line is the back-end-of-line, or BEOL for short, which usually contains various metal planes by means of which the integrated electronic components of the FEOL are interconnected.

A wafer comprises a plurality of regions which, following dicing/fragmenting/unification, each form a chip or die. These regions are also referred to herein as chip or die regions. Each chip region of the wafer preferably comprises a section or partial region of the, in particular, single-piece semiconductor substrate of the wafer. Preferably, each chip region further comprises one or more integrated electronic components extending in and/or on the corresponding region of the semiconductor substrate—in particular in the FEOL when viewed in cross-section. It should be emphasized that the chip regions do not represent isolated chips, i.e. the wafer does not comprise isolated chips.

It may be that the integrated electronic component(s) of several, in particular all, chip regions of the wafer are identical. In that case, a plurality of identical chips with photonic platform fabricated thereon (or a section thereof in each case) can be obtained from the device according to the invention by dicing.

A wafer conveniently has one or more markings along which the dicing can or must take place.

In the context of the present invention, a photonic platform is built up directly on the wafer even before the wafer is divided (diced) into individual chips. Since in the device according to the invention a photonic platform is fabricated, in particular built up, on a wafer, a large number of chips with integrated photonics can subsequently be obtained from this by mere dicing. Dicing can be performed in the same way as for conventional wafers without photonic platform on the back-end-of-line. In particular, existing equipment or facilities can be used for this purpose. As a result, individual chips with photonics can also be mass produced with reasonable effort.

The side of the wafer facing away from the front-end-of-line on which the photonic platform is or will be fabricated can also be referred to as the upper side of the wafer.

In a useful embodiment, the device according to the invention is characterized in that a photonic platform region fabricated thereon extends above a plurality of, in particular each, chip region of the wafer, each of the platform regions conveniently comprising at least one, preferably a plurality of waveguides and at least one, preferably a plurality of electro-optical devices connected to at least one integrated electronic component or circuit of the respective underlying chip region.

The photonic platform expediently comprises a plurality of functional units, it being particularly preferred that at least one, in particular exactly one, of the functional units extending above the respective chip region is assigned to each chip region of the wafer.

According to the invention, the photonic platform is fabricated on the back-end-of-line of the wafer, in particular after the (conventional) wafer fabrication process is fully completed. In this case in particular, it becomes possible to do without adapting the (conventional) wafer fabrication steps. The photonic platform fabrication can also be done completely separately from the (conventional) wafer fabrication. Thus, a high degree of flexibility is given.

That an integrated electronic component extends in and/or on the semiconductor substrate of the wafer of the device according to the invention in particular means that it is arranged within and/or directly on the substrate. Of course, it may be the case that an integrated electronic component extends in sections within the substrate and in sections directly on the substrate, for example directly on one or more sides of the substrate.

The semiconductor substrate of the semiconductor device according to the invention is preferably single-piece. In particular, it is a monolithic substrate. The substrate may have been manufactured in several layers.

The semiconductor substrate may further be characterized by a circular circumference. Alternatively or additionally, it may have a diameter in the range from 600 mm to 50 mm, preferably 500 mm to 100 mm. Exemplary diameters include 150 mm, 200 mm, 300 mm and 450 mm.

The fact that the photonic platform has been/is fabricated on the back-end and not on the same level as the electronics in the front-end-of-line offers the great advantage that no additional space (also referred to as “real estate”) is required there for the photonics. The sometimes existing problem of a limited real estate in the front-end is therefore not further aggravated.

That the photonic platform is/has been fabricated on the wafer means that it is/was fabricated directly on the wafer, which includes, for example, material buildup/deposition directly on the wafer(s). The photonic platform is preferably characterized by comprising material deposited on the side of the wafer facing away from the front-end-of-line. Accordingly, in the method according to the invention, it may be provided that the fabrication of the photonic platform includes depositing material on the side of the wafer facing away from the front-end-of-line. In particular, the photonic platform is not or has not been fabricated independently of the wafer, for example on another substrate, and then transferred to the wafer and bonded to the wafer, for example by bonding. Rather, it is or has been obtained on the wafer.

It may be that the photonic platform of the semiconductor device of the invention, with the possible exception of one or more electro-optical devices or components of at least one of them, does not have bonded layers.

In a particularly advantageous embodiment, the photonic platform comprises a planarization coat of a dielectric material. This is preferably fabricated on the side of the wafer facing away from the front-end-of-line. Further preferably, it may apply that the waveguide or at least one of the waveguides is fabricated on the side of the planarization coat facing away from the wafer.

Accordingly, the method according to the invention may be characterized in further detail in that the fabrication of the photonic platform includes fabricating a planarization coat of a dielectric material, in particular on the side of the wafer facing away from the front-end-of-line.

The planarization coat of the photonic platform provided according to these embodiments may form the basis for one or more photonic layers or planes, each preferably comprising at least one waveguide and/or at least one electro-optical device.

The waveguide or at least one of the waveguides can then further preferably be fabricated on the side of the planarization coat facing away from the wafer.

The fabrication of the at least one waveguide may further include that a waveguide material is applied, preferably deposited or spin-coated or transferred, in particular on the side of the planarization coat facing away from the wafer, and then preferably a structuring of the deposited waveguide material is carried out, in particular by means of lithography and/or reactive ion etching. For example, the same deposition processes can be used which are described below in connection with the planarization coat.

If the photonic platform comprises a planarization coat provided on the back-end-of-line, the planarization coat is not fabricated independently of the wafer, e.g. on another substrate, and then transferred to the wafer and bonded to the wafer, e.g. by bonding. Rather, it is or has been obtained on it. One can then also say that the planarization coat is a monolithic layer, in particular a layer monolithic with or to the wafer.

In a further elaboration, the planarization coat is characterized on its side facing away from the wafer by a roughness of less than 2.0 nm RMS, preferably less than 1.0 nm RMS, particularly preferably less than 0.3 nm RMS. For example, a lower limit may be 0.01 nm RMS. In other words, the roughness can be, for example, in the range from 2.0 nm RMS to 0.01 nm RMS, preferably in the range from 1.0 nm RMS to 0.01 nm RMS, particularly preferably in the range from 0.3 nm RMS to 0.01 nm RMS. The abbreviation nm stands here and in the following, in a manner known per se, for nanometer (10⁻⁹ m). The abbreviation RMS stands for root mean squared. The RMS roughness is also referred to in German as “quadratische Rauheit”.

In a further embodiment of the device according to the invention, the planarization coat comprises or consists of spin-on-glass and/or at least one polymer and/or at least one oxide, in particular silicon dioxide, and/or at least one nitride. Accordingly, the method according to the invention may comprise fabricating a planarization coat consisting of or comprising spin-on-glass and/or at least one polymer and/or at least one oxide, in particular silicon dioxide, and/or at least one nitride.

Spin-on-glass is usually a liquid substance with which wafers can be coated by spin-on-glass coating. After spin-on-glass coating, a layer is formed on the wafer, the thickness of which depends on the surface topology. Depressions are thus partially compensated and the spin-on-glass coating has a planarizing effect. Spin-on-glass is usually heated after deposition and thus becomes a glass-like layer.

Alternatively or additionally, it can be provided that the planarization coat is formed by deposition, in particular chemical vapor deposition (CVD), preferably low-pressure chemical vapor deposition (LPCVD) and/or plasma enhanced chemical vapor deposition (PECVD), and/or by physical vapor deposition of a coating material on the side of the wafer facing away from the front-end-of-line and preferably subsequent processing of the deposited material on the side facing away from the wafer by means of chemical-mechanical polishing and/or by means of resist planarization.

In the method according to the invention, it can accordingly be provided that at least one coating material is deposited on the side of the wafer facing away from the front-end-of-line as part of the fabrication of the planarization coat, in particular by chemical vapor deposition, preferably low-pressure chemical vapor deposition and/or plasma-assisted chemical vapor deposition, and/or by physical vapor deposition. Preferably, the deposited material is subsequently chemically-mechanically polished and/or resist planarized on the side facing away from the wafer, particularly preferably in such a way that a roughness of less than 2.0 nm, preferably less than 1.0 nm RMS, particularly preferably less than 0.3 nm RMS is obtained. The chemical-mechanical polishing and/or the resist planarization can be carried out in particular in such a way that a roughness in the range from 2.0 nm RMS to 0.01 nm RMS, preferably in the range from 1.0 nm RMS to 0.01 nm RMS, particularly preferably in the range from 0.3 nm RMS to 0.01 nm RMS is obtained.

Roughnesses in these regions have proven to be particularly suitable. They are particularly advantageous for avoiding stress and strain in overlying layers. In this context, it is also referred to the paper “Identifying suitable substrates for high-quality graphene-based heterostructures” by L. Banszerus et al, 2D Mater., Vol. 4, No. 2, 025030, 2017.

Atomic force microscopy (short: AFM) can be used as a measuring method for determining roughness, in particular as described in EN ISO 25178. Atomic force microscopy is discussed primarily in Part 6 (EN ISO 25178-6:2010-01) of this standard, which deals with measurement methods for roughness determination.

There are various prior art chemical vapor deposition processes, all of which can be used in the context of the present invention. Common to all of them is usually a chemical reaction of introduced gases, which leads to a deposition of the desired material.

Also with regard to physical vapor deposition, all variants known from the prior art can be used. Purely by way of example, electron beam evaporation, in which material is melted and evaporated by means of an electron beam, and thermal evaporation, in which material is heated to the melting point by means of a heater and evaporated onto a target substrate, as well as sputter deposition, in which atoms are knocked out of a material carrier by means of a plasma and deposited onto a target substrate, can be mentioned.

As an alternative or in addition to the above-mentioned deposition processes, atomic layer deposition is also possible. In this process, insulating or conductive materials (dielectrics, semiconductors or metals) are sequentially deposited atomic layer by atomic layer.

In chemical-mechanical polishing, an object to be polished, such as a wafer, is usually polished by a rotating movement between grinding pads. The polishing is performed chemically on the one hand and physically on the other by means of an abrasive paste. By combining the chemical and physical action, smooth surfaces can be obtained on a sub-nm scale.

In particular, resist planarization includes a single or repeated spin-on-glass deposition and subsequent etching, preferably reactive ion etching (RIE). If a surface, such as a SiO₂ surface, which has height differences is to be planarized, this can be done by spin-on-glass deposition and etching. The spin-on-glass coat partially compensates for the height differences, i.e. valleys of the topology have a higher coat thickness after spin-on-glass coating than adjacent elevations. The etch rate of spin-on-glass and, for example, SiO₂ is similar or the same in an adapted RIE process. Adapted here means in particular that the pressure, the gas flow, the composition of the gas mixture and the power are selected accordingly. If the entire spin-on-glass coat is etched by RIE after spin-on-glass coating, the height difference has been reduced due to the planarizing effect of the spin-on-glass coat. The height difference can be further reduced by repetition. The consumed SiO₂ coat thickness must be taken into account when depositing the SiO₂ coat, so that the desired SiO₂ coat thickness is achieved after completing the final etching step. It should be emphasized that resist planarization is not limited to SiO₂ but can also be considered for other materials. It is convenient if an etch rate of the material can be achieved that is similar to, or at least substantially the same as, that of spin-on-glass. For SiO₂ and spin-on-glass, this condition is met. It should be noted that, for example, materials whose etch rate differs from that of spin-on-glass by a factor of 2 are also possible, in which case several passes are generally necessary. Hydrogen silsesquioxane and/or a polymer, for example, can be applied as a liquid material, in particular spun on. It vitrifies during subsequent annealing, which is why it is also referred to as spin-on glass. Hydrogen silsesquioxane (HSQ) is a class of inorganic compounds with the formula [HSiO_{3/2}]ₙ.

In a further advantageous embodiment, the photonic platform comprises at least one further planarization coat. The planarization coat or—in case of several—at least one of the further planarization coats can then preferably be made of the same material as the planarization coat. It can also be or be manufactured in the same way as the planarization coat. However, this is to be understood as optional and not restrictive.

The further planarization coat or—in the case of several—one of the further planarization coats can be arranged or fabricated on the at least one waveguide and/or the planarization coat.

In the method according to the invention, it can be provided accordingly that at least one further planarization coat is preferably fabricated following the fabrication of the at least one waveguide. The fabrication of the at least one further planarization coat particularly preferably includes that a coating material is applied, in particular deposited, to the side of the at least one waveguide and/or the planarization coat facing away from the wafer.

The coating material of the further planarization coat can—in complete analogy to the planarization coat—be or have been subjected to a planarization treatment, in particular chemical-mechanical polishing and/or resist planarization, at least on its side facing away from the wafer. Again, this is or has preferably been carried out in such a way that a roughness of the side facing away from the wafer of less than 2.0 nm, preferably less than 1.0 nm RMS, particularly preferably less than 0.3 nm RMS is obtained. Also with regard to the at least one further planarization coat, it is preferably the case that the chemical-mechanical polishing and/or the resist planarization are carried out in such a way that a roughness in the range from 2.0 nm RMS to 0.01 nm RMS, preferably in the range from 1.0 nm RMS to 0.01 nm RMS, particularly preferably in the range from 0.3 nm RMS to 0.01 nm RMS is obtained.

The fabrication of the planarization coat and/or the further planarization coat may further include applying a further coating material to the treated side following the planarization treatment. The treated side may also be referred to as the upper side.

Furthermore, it can be provided that the planarization coat and/or the further planarization coat or a further planarization coat comprise one or more cover layers which are preferably provided on the surface subjected to the planarization treatment and which can be, for example, dichalcogenide layers or dichalcogenide heterostructures or also boron nitride layers. These materials are preferably deposited or transferred without the need for further chemical-mechanical polishing or further resist planarization, although it is also not excluded that this is carried out again.

Of course, it is possible for the photonic platform to include other layers in addition to one or more planarization coats and/or one or more top coats.

A coat can comprise only exactly one or also several layers. It may consist of only one material or it may comprise several materials. For example, a coat may have two or more layers of two or more different materials. Of course, it is also possible for a coat to have multiple layers, but they may all be made of the same material. In particular, a coat with more than one layer can be obtained or be present because several layers, for example several atomic layers, are or were provided, for example deposited, for the fabrication thereof.

Furthermore, also with respect to the waveguide(s) of the device according to the invention, these are not bonded to the underlying coat, but rather these are or were fabricated on the underlying coat, in particular the planarization coat, or also the wafer. For example, a suitable waveguide material is or has been provided on the planarization coat, for example built up or deposited thereon, and then, if necessary, structured to obtain the waveguide(s), for example by lithography and/or etching. Lithography preferably includes, in a manner known per se, applying a photosensitive resist, in particular spinning it on and exposing it to light, in particular UV light. Parts that are not to be exposed are conveniently covered with a mask. After development, the structure on the mask is transferred to the resist coat.

It may be that the waveguide or at least one of the waveguides or also all waveguides are embedded in a coat and/or extend between two coats. For example, one or more of the waveguides may be considered to be embedded in the further planarization coat or at least one of the further planarization coats. One or more waveguides extending between two coats and embedded in a coat may, for example, be obtained by fabricating the waveguide(s) on the side of the planarization coat facing away from the wafer and then fabricating a further planarization coat on the waveguide(s), the fabrication including applying, in particular depositing, a coating material on the waveguide(s) and the non-covered regions of the underlying planarization coat.

In a preferred embodiment, the waveguide or—in the case of several waveguides—at least one of the waveguides of the photonic platform comprises at least one material that is transparent to electromagnetic radiation of a wavelength of 850 nm and/or 1310 nm and/or 1550 nm or consists of such a material. Particularly preferably, it is transparent to electromagnetic radiation in the wavelength range from 800 nm to 900 nm and/or from 1260 nm to 1360 nm (so-called original band or O-band for short) and/or 1360 nm to 1460 nm (so-called extend band or E-band for short) and/or 1460 nm to 1530 nm (so-called short band or S-band for short) and/or from 1530 nm to 1565 nm (so-called conventional band or C-band for short) and/or 1565 nm to 1625 nm (so-called long band or L-band for short). These bands are known from the field of communication engineering.

The waveguide or—in the case of several—at least one of the waveguides of the photonic platform of the semiconductor device according to the invention may, in a further advantageous embodiment, comprise titanium dioxide and/or aluminium nitride and/or tantalum pentoxide and/or silicon nitride and/or aluminium oxide and/or silicon oxynitride and/or lithium niobate and/or silicon, in particular polysilicon, and/or indium phosphite and/or gallium arsenide and/or indium gallium arsenide and/or aluminium gallium arsenide and/or at least one dichalcogenide, in particular two-dimensional transition metal dichalcogenide, and/or chalcogenide glass and/or resins or resin-containing materials, in particular SU8, and/or polymers or polymer-containing materials, in particular OrmoComp, or consist of one or more of these materials. In the method according to the invention, preferably at least one waveguide comprising or consisting of one of these materials or comprising or consisting of a combination of one or more of these materials is fabricated.

The at least one waveguide expediently consists of or comprises a material, whose refractive index differs from the refractive index of a material or materials of the planarization coat and/or the further planarization coat, if present. This in particular if the at least one waveguide has a common interface with the planarization coat and/or the further planarization coat.

Purely exemplary pairs of refractive indices include 3.4 (Si) for the waveguide(s) and 1.5 (SiO2) for the planarization coat(s) or, in the case of dielectrics, 2.4 (TiO2) for the waveguide(s) and 1.5 (SiO2) for the planarization coat(s) or 2 (SiN) for the waveguide(s) and 1.47 for the planarization coat(s).

If at least one further planarization coat is provided, it can also apply with regard to the further planarization coat that it consists of a material or comprises a material whose refractive index differs from the refractive index of the material of the at least one waveguide. This applies in particular if it is in contact with at least one waveguide, i.e. has or forms a common interface with the latter.

It is particularly preferred that the refractive index of the material of the waveguide(s) is at least 20%, preferably at least 30%, greater than the refractive index of the material of the planarization coat and/or the further planarization coat.

In these embodiments, in other words, a refractive index contrast has been or is realized between at least one waveguide and the planarization coat and/or at least one waveguide and the further planarization coat, if present.

A waveguide is an element or component that guides an electromagnetic wave, in particular light. In order to guide the wave, a wavelength-dependent cross-section of a material, which is optically transparent for at least this wavelength and which is distinguished from an adjacent material, which is also transparent for this wavelength, by a refractive index contrast is expediently provided. If the refractive index of the surrounding material is lower, the light is guided in the region of higher refractive index. For the particular case of a slit mode, two regions of high refractive index are separated from a region of low refractive index that is narrow with respect to the wavelength, and the light is guided in the region of low refractive index. To achieve low losses due to scattering, a low sidewall roughness is advantageous.

With respect to the dimensions of the waveguide(s), the following may apply in particular. The thickness is preferably in the range from 150 nanometers to 10 micrometers. The width and length of the waveguide(s), i.e., the lateral extent parallel to the wafer surface, may in particular be in the range of 100 nanometers and 10 micrometers.

One or more waveguides can be designed, for example, as strip waveguides, which are characterized, for example, by a rectangular or square cross-section. One or more waveguides may alternatively or additionally be formed as ridge waveguides with a T-shaped cross-section. Further alternatively or additionally, it is possible that one or more waveguides are given by slot waveguides.

One or more waveguides of the device according to the invention may, for example as viewed in cross-section, comprise several sections or segments and may be formed in several parts, for example comprising or consisting of a first, for example lower or left, and a second, for example upper or right, segment, in other words part or section. It may be that one or more waveguide segments are characterized by a rectangular or square cross-section. If a waveguide comprises or consists of two or more segments, these may be adjacent to or merge into one another or may also be spaced apart from one another, for example forming a gap or slot.

The photonic platform provided according to the invention expediently comprises several waveguides. Then it can be further provided that at least two waveguides extend at least in sections one above the other. In other words, two or more planes of waveguides then exist or are “stacked” on top of each other, whereby further space can be saved and more complex circuits with extended function can be obtained.

In addition, passive structures can be made from waveguides, e.g. a multimode interference coupler (MMI) i.e. a 50:50 splitter based on interference, or a directional coupler where two waveguides run side by side over a certain length and couple the light from one into the other. One can also obtain Mach-Zehnder interferometers, for example (2×50/50 MMI as splitters and two arms in between).

A further embodiment is characterized in that, in addition to the at least one electro-optical device, the photonic platform also comprises at least one optical device, in particular at least one interferometer, such as a Mach-Zehnder interferometer, and/or at least one interference coupler, such as a multimode interference coupler, and/or at least one directional coupler and/or at least one polarization converter and/or at least one splitter and/or at least one ring resonator. The at least one optical device preferably comprises or is formed by one or more waveguides and/or waveguide sections. In particular, it may comprise only a part or section of the waveguide as viewed in the longitudinal direction of the waveguide, in other words a longitudinal section. An optical device formed as a ring resonator expediently comprises a preferably self-contained, ring-shaped waveguide forming a resonator and a preferably straight waveguide section coupled thereto. The coupling can be realized via a directional coupler, which preferably comprises or is formed by a region in which the distance between the ring-shaped waveguide and the straight waveguide section is such that light couples between the two.

Accordingly, the method according to the invention may be characterized in that at least one optical device is fabricated, preferably at least one interferometer, such as Mach-Zehnder interferometer, and/or at least one interference coupler, such as multimode interference coupler, and/or at least one directional coupler and/or at least one polarization converter and/or at least one splitter and/or at least one ring resonator.

Also, the photonic platform may include one or more thermo-optical devices. One such device includes, for example, a heating element and a longitudinal section of a waveguide, the heating element being arranged relative to the waveguide portion such that it can heat the waveguide portion. The heating element may, for example, be one whose temperature increases when current passes through it. For example, the heating element may be arranged in the vicinity of the waveguide. Heating the waveguide by means of the heating element can change the refractive index of the waveguide. This effect can be used, for example, for phase matching. A thermo-optical device can also be associated with or form part of an interferometer of the photonic platform.

In a further embodiment, the photonic platform has a passivation coat and/or a cladding on its side facing away from the wafer. The photonic platform preferably terminates with a passivation coat and/or a cladding. In other words, the passivation coat and/or the cladding form the last or top coat(s) of the photonic platform.

A cladding is particularly suited or designed to make the index contrast somewhat lower, so that roughnesses on the sidewalls do not have quite as much of an effect; usually the losses go back into the waveguide(s).

A passivation coat preferably serves the purpose of protecting the arrangement or circuit from environmental influences, in particular water. A passivation coat can, for example, consist of a dielectric material. Aluminium oxide (Al₂ O₃) and silicon dioxide (SiO₂) have proved particularly suitable.

An upper, final passivation coat expediently has openings or interruptions to underlying contacts to enable electrical connection. Openings or interruptions in a passivation coat can be or have been obtained, for example, by lithography and/or etching, in particular reactive ion etching.

Reactive ion etching is a dry etching process in which selective and directional etching of a substrate surface is usually made possible by means of special gaseous chemicals that are excited to form a plasma. A resist mask can be used to protect parts that are not to be etched. The etch chemistry and parameters of the process usually determine the selectivity of the process, i.e., the etch rates of different materials. This property is crucial for limiting the depth of an etching process and thus defining coats separately from each other.

In a further advantageous embodiment, the semiconductor device according to the invention is characterized in that the back-end-of-line of the wafer and the photonic platform comprise interconnection elements through which the integrated circuit or at least one of the integrated circuits of the wafer is connected to the electro-optical device or at least one of the electro-optical devices of the photonic platform.

Accordingly, in the method according to the invention, in an advantageous further development, it can be provided that the back-end-of-line of the provided wafer comprises interconnection elements connected to the integrated circuit or at least one of the integrated circuits of the front-end-of-line, and interconnection elements are fabricated in the photonic platform which are connected, on the one hand, to the interconnection elements of the back-end-of-line and, on the other hand, to the electro-optical device or at least one of the electro-optical devices.

The interconnection elements may be, in particular, vertical electrical interconnects, also known in English as Vertical Interconnect Access, or Via or VIA. The VIAs are usually defined by lithography and dry-chemically etched using RIE. Afterwards, metallization is preferred and the metallized surface is structured by CMP (Damascene process) or by lithography and RIE.

The interconnection elements expediently comprise or consist of at least one electrically conductive material, in particular metal, such as copper and/or aluminium and/or tungsten.

In a further embodiment, the electro-optical device(s) or at least parts thereof may also be or have been fabricated on one or more of the waveguides and/or the side of the planarization coat facing away from the wafer and/or the side of a further planarization coat, if present, facing away from the wafer.

The electro-optical device(s) of the semiconductor device according to the invention can in principle be any device designed to generate and/or transmit and/or receive optical signals. In particular, it can or may be devices for optical data communication, and/or spectrometers, and/or adjustable electro-optical filters and/or switches and/or attenuators, in particular for machine learning. Non-linear optical elements may also be included.

An electro-optical device designed as a filter may comprise, for example, a ring resonator, preferably in combination with a modulator.

The electro-optical device or—in the case of several—at least one electro-optical device or also each electro-optical device comprises in a practical embodiment at least two contacts or contact elements, which serve in particular for contacting the active element or in each case an active element with an interconnection element.

Preferably, the electro-optical device or—in case of several—at least one or also each electro-optical device further comprises at least one active element. In addition to at least one active element, an electro-optical device may comprise a section, in particular a longitudinal section, of a waveguide. It is also possible that an active element of an electro-optical device or a section thereof forms a waveguide or at least a section, in particular a longitudinal section of a waveguide. It is also possible that several, for example two, active elements or sections of such together form a waveguide or a section, in particular a longitudinal section of a waveguide, for example a ridge waveguide. Then, expediently, the active element or elements consist of a material, which is transparent to electromagnetic radiation of at least one wavelength, preferably of at least one wavelength range. Preferably, it then applies that the at least one material is transparent for electromagnetic radiation of a wavelength of 850 nm and/or 1310 nm and/or 1550 nm. Particularly preferred it is transparent for electromagnetic radiation in the wavelength range from 800 nm to 900 nm and/or from 1260 nm to 1360 nm (so-called original band or O-band for short) and/or 1360 nm to 1460 nm (so-called extend band or E-band for short) and/or 1460 nm to 1530 nm (so-called short band or S-band for short) and/or from 1530 nm to 1565 nm (so-called conventional band or C-band for short) and/or 1565 nm to 1625 nm (so-called long band or L-band for short).

If at least one active element is provided, it is preferred that this comprises or consists of at least one material, which absorbs electromagnetic radiation of at least one wavelength, preferably at least one wavelength range, and generates an electrical photosignal as a result of the absorption and/or whose refractive index changes as a function of a voltage and/or the presence of charge(s) and/or an electrical field. Preferably, it then applies that the at least one material can absorb electromagnetic radiation of a wavelength of 850 nm and/or 1310 nm and/or 1550 nm and generate a photosignal as a result of the absorption. It is particularly preferred that it can absorb electromagnetic radiation in the wavelength range from 800 nm to 900 nm and/or from 1260 nm to 1360 nm (so-called original band or O-band for short) and/or from 1360 nm to 1460 nm (so-called extend band or E-band for short) and/or from 1460 nm to 1530 nm (so-called short band or S-band for short) and/or from 1530 nm to 1565 nm (so-called conventional band or C-band for short) and/or from 1565 nm to 1625 nm (so-called long band or L-band for short) and can generate a photosignal as a result of the absorption.

That a material changes its refractive index is to be understood in particular in that it changes its dispersion (in particular refractivity) and/or its absorption. The dispersion or refractivity is usually given by the real part and the absorption by the imaginary part of the complex refractive index. Materials whose refractive index changes as a function of a voltage and/or the presence of charge(s) and/or an electric field are understood herein to be, in particular, those characterized by the Pockels effect and/or the Franz-Keldysh effect and/or the Kerr effect. In addition, materials characterized by the plasma dispersion effect are also considered to be such materials.

Exemplary materials for the active element(s) are graphene, possibly chemically modified graphene, and/or germanium and/or lithium niobate and/or electro-optical polymers and/or silicon and/or compound semiconductors, such as III-V semiconductors and/or II-VI semiconductors, and/or dichalcogenides, in particular two-dimensional transition metal dichalcogenides, and/or heterostructures of two-dimensional materials. 2D materials other than graphene are thus also possible, both alternatively and additionally. Electro-optical polymers in particular are to be understood as polymers characterized by having a strong linear electro-optical coefficient (Pockels effect). A strong linear electro-optical coefficient is preferably to be understood as such that amounts to at least 150 pm/V, preferably at least 250 pm/V. The electro-optical coefficient is at least about five times that of lithium niobate then.

There are different chalcogenides. In the context of the present invention, transition metal dichalcogenides as two-dimensional materials, such as MoS2 or WSe2, have proved particularly suitable.

It should be noted that lithium niobate and electro-optical polymers are based on the electro-optical, in particular the Pockels effect, i.e. the E-field changes the refractive index (as e.g. the Pockels effect is used in the Pockels cell). In germanium, it is the Franz-Keldysh effect, i.e., the field shifts the valence and conduction band edges with respect to each other, changing the optical properties. These effects are field-based effects. For silicon or graphene, it is the charge carrier-based plasma dispersion effect, i.e., charge carriers (electrons or holes) are brought into the optical mode region (either there is a capacitor in the device that is charged or a diode with a junction that is depleted and enriched). The refractive index (real part of the index) and the absorption (imaginary part of the index, leading to free carrier absorption) change with the charge carrier concentration.

III-V semiconductors are compound semiconductors consisting of elements of main groups III and V in a manner known per se. II-VI semiconductors are compound semiconductors consisting of elements of main group II or group 12 elements and elements of main group VI.

Graphene, among other materials, has proven to be a particularly suitable material for the active element(s) of the electro-optic device(s) of the semiconductor device of the invention.

Many materials are characterized both by the fact that their refractive index changes as a function of a voltage and/or the presence of charge and/or an electric field, and by the fact that they absorb electromagnetic radiation of at least one wavelength and generate an electric photosignal as a result of the absorption. For graphene, for example, this is the case. Graphene is accordingly suitable for both the active elements of photodetectors and modulators. This also applies to dichalcogenides, such as two-dimensional transition metal dichalcogenides, heterostructures of two-dimensional materials, germanium, silicon, as well as compound semiconductors, in particular III-V semiconductors and/or II-VI semiconductors. Lithium niobate, for example, is generally only suitable for modulators. Since it is transparent, it does not fulfil the absorbing property and is therefore not suitable for photodetectors.

It may be that the at least one active element of one or more electro-optical devices is in the form of a film. A film is preferably characterized in a manner known per se by a significantly greater lateral extent than thickness. The at least one active element of one or more electro-optical devices may further be characterized by a square or rectangular cross-section.

One or more active elements may comprise one or more layers or coats of at least one material whose refractive index changes and/or which absorbs, or may be formed from one or more layers or coats of at least one such material. In particular, it may be provided that at least one active element is formed as a film comprising a plurality of coats or layers of one or also different materials.

Films of graphene, possibly chemically modified graphene, or dichalcogenide-graphene heterostructures consisting of at least one layer of graphene and at least one layer of a dichalcogenide or arrays of at least one layer of boron nitride and at least one layer of graphene have proven to be particularly suitable.

Active elements can, for example, also comprise or be provided by one or more silicon coats. In this case, in particular, it can be provided that one or more active elements or sections thereof form a waveguide (section).

The active element(s) may further be doped or have doped sections or regions, for example be p-doped and/or n-doped or comprise corresponding sections or regions. It may also be that a p-doped region and an n-doped region and a preferably intermediate undoped region are present or provided. This is also referred to as pin-transition, where the i stands for intrinsic, i.e. undoped.

A further advantageous embodiment is characterized in that an active element is provided which has a p-doped region and an n-doped region, the two doped regions being adjacent to one another or an undoped region being located between them, and the two doped regions optionally together with the possibly intermediate undoped region jointly forming a waveguide or a section of such a waveguide.

Also, an element or coat of an electro-optical polymer can be provided between two active elements, for example of doped silicon.

Furthermore, it can be provided that for obtaining active elements for a plurality of electro-optical devices at least one film or coat (with one or also several layers) extending optionally over the entire lateral extent of the wafer is or was provided, for example deposited, and from this large film a plurality of smaller film- or coat-shaped active elements lying next to each other in one plane is or has been obtained for the plurality of devices by a suitable structuring process which can include, for example, lithography and/or etching. Thus, with comparatively little effort, many active elements can be obtained for a plurality of electro-optical devices.

Alternatively or additionally, the active element or at least one of the active elements may be or have been provided by a transfer process. This means in particular that the respective element(s) is/are not monolithically fabricated on the wafer or a coat fabricated thereon, but is/are fabricated separately and then transferred, in other words has/have been transferred. For example, a transfer process for graphene is described in the papers “Large-Area Synthesis of High-Quality and Uniform Graphene Films on Copper Foils,” by Li et al, Science 324, 1312, (2009) and “Roll-to-roll production of 30-inch graphene films for transparent electrodes” by Bae et al, Nature Nanotech 5, 574-578 (2010) or for LiNbO from the paper “Integrated lithium niobate electro-optic modulators operating at CMOS-compatible voltages,” Nature volume 562, pages 101104 (2018) or inter alia for GaAs from the paper “Transfer print techniques for heterogeneous integration of photonic components,” Progress in Quantum Electronics Volume 52, March 2017, Pages 1-17. One of these methods can also be used in the context of the present invention to obtain one or more graphene or LiNbO or GaAs coats/films.

Structuring can also follow a transfer process.

In a further embodiment, it is provided that the electro-optical device or at least one of the electro-optical devices is given by a modulator comprising an active element, which comprises or consists of at least one material, whose refractive index changes as a function of a voltage and/or the presence of charge and/or an electric field, and a further active element comprising or consisting of at least one material, whose refractive index changes as a function of a voltage and/or the presence of charge and/or an electric field, or an electrode, the two active elements or the active element and the electrode are preferably spaced apart from one another and are arranged offset from one another in such a way that they lie one above the other in sections. The at least one corresponding material of the one or the two active elements may be graphene and/or at least one dichalcogenide, in particular two-dimensional transition metal dichalcogenide, and/or heterostructures of two-dimensional materials and/or germanium and/or lithium niobate and/or at least one electro-optical polymer and/or silicon and/or at least one compound semiconductor, in particular at least one III-V semiconductor and/or at least one II-VI semiconductor.

In other words, one active element and one conventional electrode are sufficient for a modulator as an alternative to two active elements. In particular, the electrode then does not consist of at least one material, whose refractive index changes, or does not comprise such a material, but at least one electrically conductive material. If an electrode is provided instead of one of the active elements, this can be in the form of a film, possibly with multiple layers, such as a single-layer or multilayer metal film, by analogy with the active element.

Also in the case of the modulator, the active element(s) preferably comprise(s) graphene, optionally chemically modified graphene, and/or at least one dichalcogenide, in particular two-dimensional transition metal dichalcogenide, and/or heterostructures of two-dimensional materials and/or germanium and/or lithium niobate and/or at least one electro-optical polymer and/or silicon and/or at least one compound semiconductor, in particular at least one III-V semiconductor and/or at least one II-VI semiconductor.

The two active elements or the one active element and the electrode are preferably arranged at a distance from each other and/or offset from each other in such a way that they lie one above the other in sections. In other words, a section of one active element then aligns or overlaps with a section of the other active element or the electrode, if necessary even without these touching. Preferably, at least in the region of lying above the other, in other words in the overlapping region, the two active elements or the active element and the electrode or at least sections thereof extend at least substantially parallel to each other.

Also in the case of a modulator with two active elements or one active element and a conventional electrode, it may further apply that the respective active element or the one active element and the electrode are formed as a film.

An electro-optical modulator can be used in particular for optical signal coding. An electro-optical modulator can also be designed as a ring modulator.

Alternatively or additionally, the electro-optical device or at least one of the electro-optical devices may be given by a photodetector comprising one, preferably exactly one, active element comprising or consisting of at least one material which absorbs electromagnetic radiation of at least one wavelength, preferably of at least one wavelength range, and generates an electrical photosignal as a result of the absorption, in particular graphene and/or at least one dichalcogenide, in particular two-dimensional transition metal dichalcogenide, and/or heterostructures of two-dimensional materials and/or germanium and/or silicon and/or at least one compound semiconductor, in particular at least one III-V semiconductor and/or at least one II-VI semiconductor.

In a photodetector, the at least one electro-optically active material is useful for absorbing light.

In particular, a photodetector can be used for signal conversion back from the optical to the electronic world.

The electro-optical device or at least one electro-optical device—both in the case of a modulator and in the case of a detector—may further be designed or—in the case of the method according to the invention—fabricated as such with plasmonic coupling.

Then, expediently, at least one plasmonic structure consisting of or comprising a plasmonically active material, preferably gold and/or silver and/or aluminium and/or copper, is provided on or above the active element or at least one of the active elements. The plasmonic structure preferably comprises at least one pair of plasmonic elements arranged next to one another and consisting of or comprising the plasmonically active material. The plasmonic elements may be characterized by a section tapering in the direction of the respective other plasmonic element. For example, the plasmonic elements may be characterized by a triangular shape.

Elongated plasmonic elements may also be provided, preferably in the case of a modulator. Elongated plasmonic elements may be/have been arranged at least substantially parallel to a waveguide. Then, in other words, optical and plasmonic waveguides are guided past the active element in parallel, as described in “Efficient electro-optic modulation in low-loss graphene-plasmonic slot waveguides,” by Zhu et al, Optics Communications (2019), doi: https://doi.org/10.1016/j.optcom.2019.124559.

The responsivity of photodetectors comprising graphene in particular can be enhanced by plasmonically enhanced absorption. For example, plasmonic structures are fabricated on a graphene channel as an active element provided on a waveguide as shown in Ma et al, “Plasmonically Enhanced Graphene Photodetector Featuring 100 Gbit/s Data Reception, High Responsivity, and Compact Size,” ACS Photonics 2019, 6, pages 154 to 161 (2018). Resonant density fluctuations in the plasmonic structures are excited by the optical mode. This collective motion of electron distribution is called plasmon and propagates in the plasmonic structure. Characteristics include a higher electric field strength compared to the optical mode. This results in a stronger absorption in graphene or generally in an absorbing material.

A further embodiment is characterized in that on at least one side of the active element or at least one of the active elements a waveguide is provided having an end section tapering in the direction of the active element or the at least one active element, preferably ending in a tip. The tapering end section may extend up to the active element or the at least one active element. Alternatively or additionally, a contact element may be provided on each of two sides of the tapering section, which contact element is connected to the active element and has a section tapering in the opposite direction and lying next to the tapering end section of the waveguide.

It can also be provided that on two sides of the active element or the at least one active element in each case a waveguide is provided with an end section tapering in the direction of the active element, preferably ending in a tip. Then it can apply to both end sections that they extend up to the active element or the at least one active element. Also, on two sides of the respective tapering section, a contact element may be provided in each case, which is connected to the active element or the at least one active element and which has a tapered section lying next to the respective tapering end section of the waveguide and tapering in the opposite direction. It may be that two contact elements are provided and each contact element has two widening sections, preferably on opposite sides and one for each end section. The respective widening section of the contact element preferably follows the taper of the respective waveguide end section. It may follow such that the distance between the tapering waveguide end and the widening contact element sections adjacent to it on either side remains the same in the direction of the active element. However, it may also increase or decrease, at least to a certain extent.

In particular, in this embodiment, it may further be provided that the active element comprises or consists of at least one electro-optical polymer (see also the publication “Silicon-Organic Hybrid (SOH) and Plasmonic-Organic Hybrid (POH) Integration,” by Koos et al, Journal of Lightwave Technology, Vol. 34, No. 2, 2016).

In other words, plasmonic coupling can also occur without waveguides under the absorbing material, i.e. a transition of the optical mode to a plasmonic mode takes place, with the plasmonic mode then interacting with the absorbing material. This is also described—in the context of a photodetector—in the publication “Ultra-compact integrated graphene plasmonic photodetector with bandwidth above 110 GHz” by Ding, Y., Cheng, Z., Zhu, X., et al. (2019), Nanophotonics, doi:10.1515/nanoph-2019-0167. In the context of modulators, it is further referred to the publication “Efficient electro-optic modulation in low-loss graphene-plasmonic slot waveguides” by Ding et al., Nanoscale, 2017, 9, 15576.

In particular, a modulator as an electro-optical device may alternatively or additionally further comprise two active elements, each given by a silicon film or coat. For example, it may be one coat or film comprising or consisting of polysilicon and one comprising or consisting of crystalline silicon. It may also be that both active elements comprise or consist of polysilicon. Of the two active elements, one is then preferably p-doped and the other n-doped. The different doping results in a capacitance. The two active elements are then preferably arranged offset to each other in such a way that they overlap in sections. The overlapping region then preferably forms a waveguide or waveguide section. By applying a voltage, the charge carrier concentration in the region of the waveguide or waveguide section, i.e. in the operation of the optical mode, can be varied and thus an optical signal can be encoded. A corresponding silicon-based modulator is also described in the paper “An efficient MOS-capacitor based silicon modulator and CMOS drivers for optical transmitters,” by M. Webster et el, 11th International Conference on Group IV Photonics (GFP), Paris, 2014, pp. 1-2. doi: 10.1109/Group4.2014.6961998.

When the electro-optical device or at least one of the electro-optical devices is or becomes a modulator, it may further be provided that it comprises a diode or capacitor. In particular, it may be an integrated III-V semiconductor modulator as described in the paper “Heterogeneously integrated III-V/Si MOS capacitor Mach-Zehnder modulator” by Hiaki, Nature Photonics volume 11, pages 482-485 (2017).

If a diode has been or is provided for the electro-optical device or at least one electro-optical device, it may comprise, for example, a plurality of coats of different compositions of, for example, InGaAsP, in particular to create a pn-junction and two contact regions.

The active element(s) and, if applicable, the electrode of one or more electro-optical devices can be provided, for example, on the side of the planarization coat facing away from the wafer or on a further planarization coat fabricated in particular on the waveguide(s). The respective element(s) may be connected to a contact or contact element on one side or on opposite sides, respectively. The contacts or contact elements can be connected to one or more electronic components from the front-end-of-line by interconnection elements, in particular VIAs. The interconnection elements, in particular VIAs, can extend through the planarization coat, the further planarization coat, if present, and the semiconductor substrate to the electronic component or components. By connected, it is expedient to understand electrically conductively connected.

It should be noted that in particular in the case of a detector with only one active element, it can be provided that the active element—in particular for connection with one or more electronic components from the front end-of-line—is in contact with two contacts or contact elements, preferably on opposite sides, and in the case of a modulator with two active elements or one active element and one electrode, it applies that these—in particular for connection with one or a plurality of electronic components from the front-end-of-line—are each in contact with one contact or contact element. This is preferably the case at those end regions or ends that face away from the region in which they overlap in sections.

It is also possible that at least one active element is/are provided on the side of one or more waveguides facing away from the wafer. This offers the advantage that the active element is closer to the waveguide(s). Then, more interaction between the active element(s) and an optical mode in the waveguide can be achieved. Furthermore, since another planarization coat is not required in this case, a shorter component can be obtained and fewer process steps are required.

In another embodiment, the active element(s) is/are provided on the side of one or more control electrodes facing away from the wafer, preferably on the side of one or more control electrodes facing away from the wafer, which control electrode or control electrodes in turn is/are fabricated on the side of one or more waveguides facing away from the wafer.

It should be noted that the side of an element facing away from the wafer may also be referred to as the upper side thereof. For example, the side of a planarization coat, a further planarization coat, a waveguide, a waveguide base, deposited material, a graphene film, a control electrode, and/or a photonic platform facing away from the wafer may also be referred to as the upper side.

In the case of a modulator with two active elements or one active element and one electrode, it can also be provided that a passivation coat is provided between the two active elements or between the active element and the electrode. A passivation coat expediently consists of a dielectric material. Accordingly, it can also be referred to as a dielectric coat. It can simultaneously form an etching protection. Oxides or nitrides are particularly suitable materials for such a coat. Aluminium oxide, silicon nitride and hafnium oxide have proved particularly suitable. If a passivation coat is provided between the two active elements or the active element and the electrode, there is preferably a sandwich-like structure with active element, passivation coat and active element or electrode, the two active elements or the active element and the electrode preferably being laterally offset from one another.

It is also possible that the active element(s) and an electrode, if any, of at least one electro-optical device extend in sections on one or more waveguides and in sections on the planarization coat(s) or further planarization coat(s) or one or more control electrodes.

Furthermore, it is possible that one or more active elements are provided at least in sections, possibly also completely, within the waveguide or at least one of the waveguides or between two parts of a waveguide.

The active element or at least one of the active elements is expediently arranged relative to at least one waveguide such that it is exposed, at least in sections, to the evanescent field of electromagnetic radiation guided by the waveguide. Preferably, at least one active element is arranged at a distance less than or equal to 50 nm, more preferably less than or equal to 30 nm, from at least one waveguide, for example at a distance of 10 nm.

In waveguides, part of the electromagnetic radiation, in particular light, is evanescently guided outside the waveguide. The interface of the waveguide is dielectric and accordingly the intensity distribution is described by the boundary conditions according to Maxwell with an exponential decay. If an electro-optically active material, for example graphene, is brought onto or near the waveguide in the evanescent field, photons can interact with the material, in particular graphene.

A photodetector conveniently has an active element comprising or consisting of at least one such material and two contacts.

There are four effects in graphene that lead to photocurrent. One is the bolometric effect, according to which the absorbed energy increases the resistance of the graphene and reduces an applied DC current. The change of the DC current is then the photo signal. Another effect is the photoconductivity. Here, absorbed photons cause the charge carrier concentration to increase and the additional charge carriers reduce the resistance of the graphene because of the proportionality of the resistance to the charge carrier concentration. An applied DC current increases and the change is the photosignal. There also is a thermoelectric effect, according to which a thermoelectric voltage results from a pn-junction and a temperature gradient at this junction due to different Seebeck coefficients for the p and n region. The temperature gradient results from the energy of the absorbed optical signal. This thermoelectric voltage is the signal then. The fourth effect is due to the fact that at a pn-junction the excited electron-hole pairs are separated. The resulting photocurrent is the signal.

In case of a modulator, as explained above, an electrical control electrode and an active element, suitably insulated for this purpose, can be provided comprising or consisting of at least one material whose refractive index changes as a function of a voltage or charges or an electric field, in particular graphene, or the electrode can also be made of a corresponding material, in particular graphene, so that in operation two active elements are then together in the evanescent field and perform the electro-optical function. Graphene, for example, can change its optical properties by a control voltage. In the particularly advantageous case of a graphene-dielectric-graphene arrangement, a capacitance is created and the two films of graphene influence each other. A voltage charges the capacitance consisting of the graphene electrodes forming two active elements and the electrons occupy states in the graphene. This results in a shift of the Fermi energy (energy of the last occupied state in the crystal) to higher energies (or to lower ones due to symmetry). When the Fermi energy reaches half the energy of the photons, they can no longer be absorbed because the free states required for the absorption process are already occupied at the correct energy. Consequently, in this state, the graphene is transparent because absorption is forbidden. By changing the voltage, the graphene is switched back and forth between absorbing and transparent. A continuously shining laser beam is modulated in its intensity and can thus be used for information transmission. Likewise, the real part of the refractive index changes with the control voltage. By changing the voltage, the phase position of a laser can be modulated via the changing refractive index and thus phase modulation can be achieved. Preferably, the phase modulation is operated in a range where all states are occupied up to above half the photon energy, so that the graphene is transparent and the real part of the refractive index shifts significantly and the change of the absorption plays a minor role.

The electro-optical device or at least one of the electro-optical devices may further comprise at least one, preferably two gate electrodes. In particular, in the case of an electro-optical device embodied as a photodetector, two gate electrodes can preferably be assigned to the active element. These are then preferably embodied and arranged in such a way that the charge carrier concentration in the active element, for example graphene film, can be adjusted via these and thus, for example, a pn-transition can be obtained. The gate electrodes are then preferably arranged at a suitable distance from the active element and electrically insulated from it, for example via a dielectric coat. It may be that a dielectric coat is provided on the active element and the gate electrodes are arranged on this.

A further particularly advantageous embodiment is characterized in that the semiconductor device according to the invention, in particular its photonic platform, comprises at least one coupling device which is associated with at least one, preferably exactly one, of the waveguides. The (respective) coupling device then expediently serves for coupling electromagnetic radiation, in particular in the infrared and/or visible wavelength range, into at least one of the waveguides of the photonic platform with which the (respective) coupling device is associated, and/or for coupling electromagnetic radiation, in particular in the infrared and/or visible wavelength range, out of at least one of the waveguides of the photonic platform with which the (respective) coupling device is associated. For this purpose, it may be appropriately embodied and arranged. It should be noted that for Si photonics, it is true that it is generally only suitable for the infrared wavelength range because of the band gap, since all wavelengths shorter than 1100 nm are absorbed in Si. This is usually not the case for dielectrics, which are also transparent in the visible wavelength range, which is why they are well suited for spectroscopy.

Particularly preferably, the coupling device or at least one of the coupling devices is embodied and arranged such that electromagnetic radiation, in particular in the infrared and/or visible wavelength range, can be coupled by means thereof from an optical fiber into at least one of the waveguides of the photonic platform, and/or that electromagnetic radiation, in particular in the infrared and/or visible wavelength range, can be coupled by means thereof from at least one of the waveguides of the photonic platform into an optical fiber. Optical fibers will typically have a larger diameter than the waveguide(s), and the coupling device(s) will further preferably be configured to enable coupling in and/or out in such a case.

A coupling device may comprise a section, in particular an end section, of a waveguide with which it is associated, for example an end section tapering or widening towards the end.

In further elaboration, the at least one coupling device can have at least one grating structure, which is then designed and arranged in particular in such a way that its first diffraction order lies in the associated waveguide. Such a coupling device can also be referred to as a grating coupling device or grating coupler for short. In connection with the design and operation of grating couplers, reference should also be made to the paper “CMOS-compatible high efficiency double-etched apodized waveguide grating coupler”, Optics Express 21, 7868-7874, 2013.

If at least one coupling device is provided by a grating coupler, it is further preferred that it comprises a reflector or that a reflector is assigned to it. A reflector is particularly suitable because it can be arranged in such a way that the maximum coupling is achieved. If no reflector is present, the interface between back-end-of-line and planarization usually automatically results as a reflector because a refractive index jump exists there. If a grating coupler is provided, a reflector is also particularly advantageous for the reason that the situation—in contrast to that with the interface —is precisely defined then. For example, a metal foil or thin metal coat or a dielectric coat stack can serve as a reflector, so that a Bragg reflector is created.

A reflector is preferably arranged in the planarization coat. A reflector can consist of or comprise metal, e.g. aluminium, and/or be characterized by a rectangular shape and/or be slightly larger than the grating coupler and/or be arranged at a suitable distance from the grating coupler, preferably below it.

Alternatively or additionally, at least one of the coupling devices can be designed as a side coupling device (side coupler for short). The coupling device then expediently has at least one coupling element which is embodied and arranged in such a way that electromagnetic radiation can be coupled into it sidewards and/or electromagnetic radiation can be coupled out of it sidewards. Sidewards means in particular sidewards with respect to the lateral extent of the wafer, in particular with respect to the side of the wafer facing away from the front-end-of-line.

In connection with the design and operation of grating couplers, it is also referred to the paper “Ultra-low-loss inverted taper coupler for silicon-on-insulator ridge waveguide,” Optics Communications Volume 283, Issue 19, October 2010, pages 3678-3682.

A grating coupling device can also be designed and arranged in such a way that the electromagnetic radiation to be coupled in can be incident from (obliquely) above, in particular on a grating thereof, or the electromagnetic radiation to be coupled out is coupled out to (obliquely) above, in particular from a grating thereof. It can further preferably be embodied and arranged in such a way that coupling can take place at an angle in the range of 0° to 30°, in particular 10° with respect to the perpendicular to the side facing away from the front-end-of-line of the wafer or of the device according to the invention.

Compared to side couplers, grating couplers with radiation entering or leaving from or to (obliquely) above usually offer the advantage that their function can be checked before dicing. In the case of side couplers, on the other hand, the side or edge of the element at which electromagnetic radiation is to enter or from which electromagnetic radiation is to exit may not be exposed until after dicing, and therefore a test can only be performed then.

In further development, it may be provided that at least two coupling devices are provided, at least one being a side coupling device (side coupler for short) and at least one being a grating coupling device (grating coupler for short). If both types of couplers are provided, a grating coupler can be used to measure the components during manufacturing and then a side coupler when everything is ready. Preferably, at least one waveguide has two couplers associated with it, one of one type and one of the other.

The coupling device or devices are preferably fabricated together with the at least one waveguide they are associated with. The fabrication may include that they are defined lithographically—in analogy to the waveguides—and structured by etching, in particular dry chemical etching.

The invention also relates to a method for manufacturing at least one semiconductor apparatus, in which a semiconductor device according to the invention is provided and fragmented, in other words diced. By the fragmenting/dicing, at least one chip, usually a plurality of chips, with photonics built thereon are obtained, each representing a semiconductor apparatus according to the invention. This “bare” chip or these “bare” chips with photonics can then, for example, each be inserted into a package. It should be noted that the semiconductor apparatus according to the invention, which comprise a conventional chip having integrated circuits and the section of the photonic platform built thereon, can in turn also be referred to as a chip.

It is further an object of the invention to provide a semiconductor device obtained by dividing, in other words dicing, a semiconductor apparatus according to the invention.

The semiconductor apparatus according to the invention, obtained by dicing a semiconductor device according to the invention, is characterized by a photonic platform or a section thereof whose lateral extent at least substantially coincides with the lateral extent of the underlying chip or semiconductor substrate. The photonic platform or the section of such has, just like the underlying substrate, obtained its shape and extension by dicing.

It may be that a housing surrounding the semiconductor apparatus is provided. In this case, it is preferred that the side of the device on which the front-end-of-line is located is in contact with the inside of the housing.

With respect to embodiments of the invention, reference is also made to the subclaims and to the following description of several embodiments with reference to the accompanying drawing.

In the Drawing Shows:

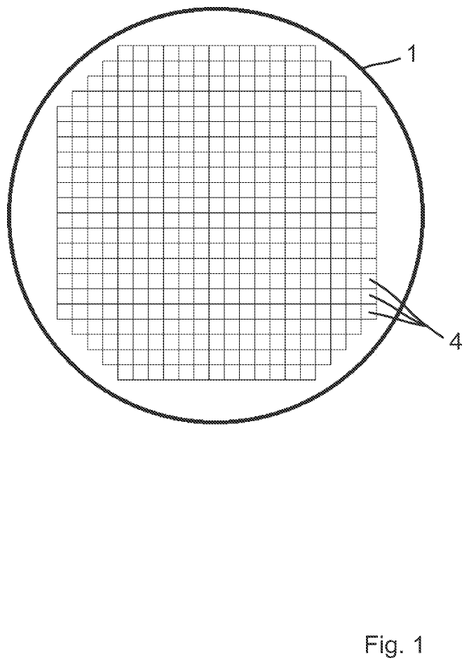

FIG. 1 a top view of an embodiment of a semiconductor device according to the invention in purely schematic representation;

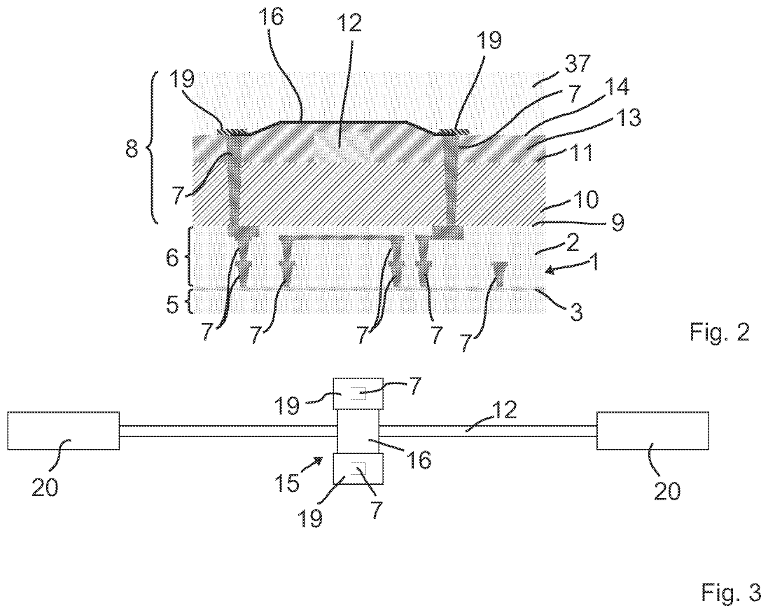

FIG. 2 a partial section through the semiconductor device of FIG. 1 in purely schematic representation;

FIG. 3 a top view of the photodetector from FIGS. 2, 4 and 5 in purely schematic representation;

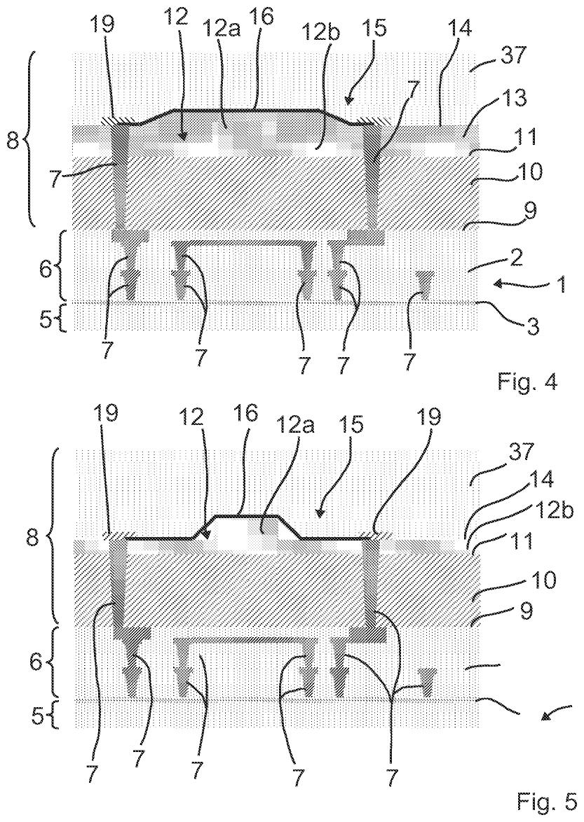

FIG. 4 a partial section through a second embodiment of a semiconductor device according to the invention in purely schematic representation;

FIG. 5 a partial section through a third embodiment of a semiconductor device according to the invention in purely schematic representation;

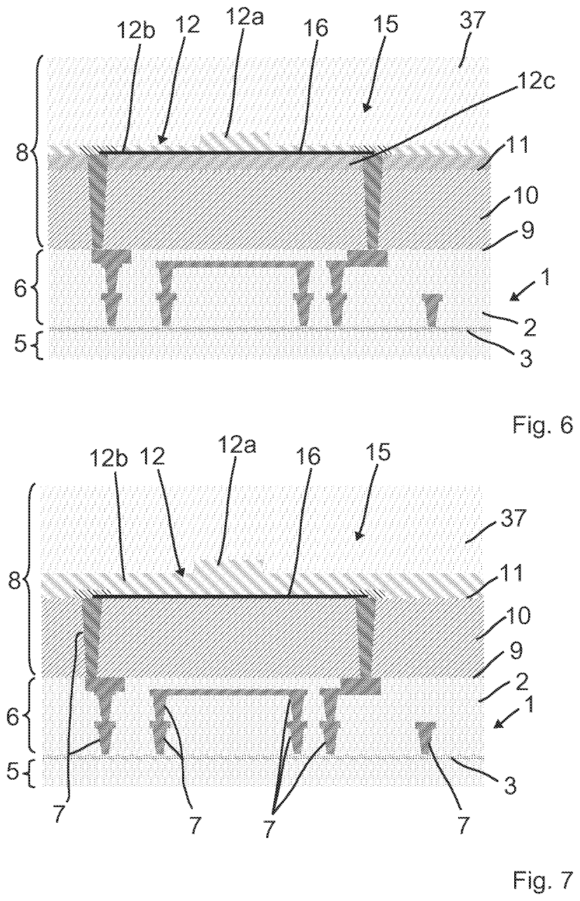

FIG. 6 a partial section through a fourth embodiment of a semiconductor device according to the invention in purely schematic representation;

FIG. 7 a partial section through a fifth embodiment of a semiconductor device according to the invention in purely schematic representation;

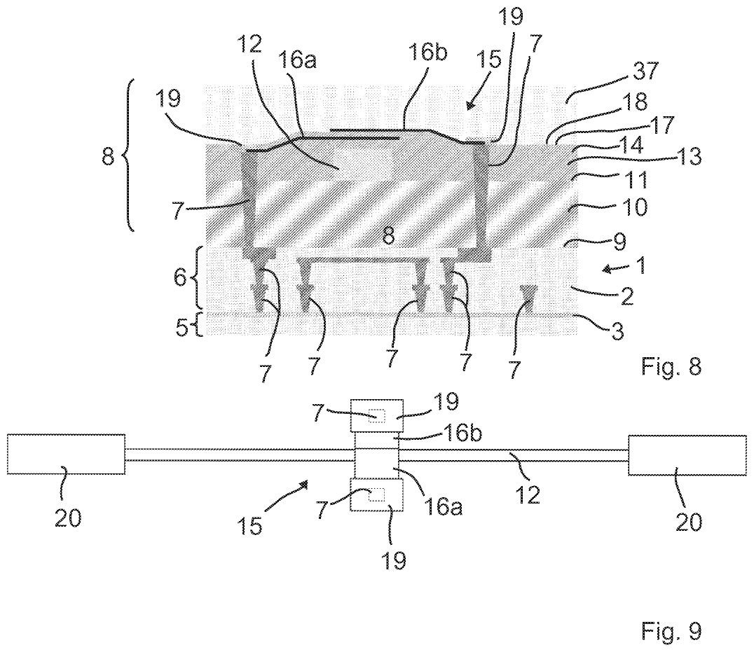

FIG. 8 a partial section through a sixth embodiment of a semiconductor device according to the invention in purely schematic representation;

FIG. 9 a top view on the modulator from FIG. 8 in purely schematic representation;

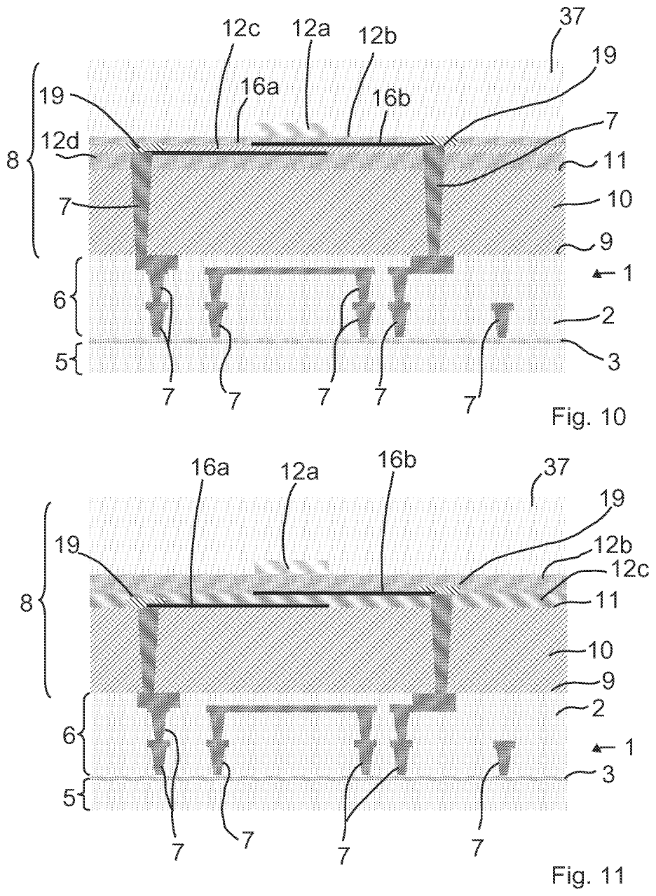

FIG. 10 a partial section through a seventh embodiment of a semiconductor device according to the invention in purely schematic representation;

FIG. 11 a partial section through an eighth embodiment of a semiconductor device according to the invention in purely schematic representation;

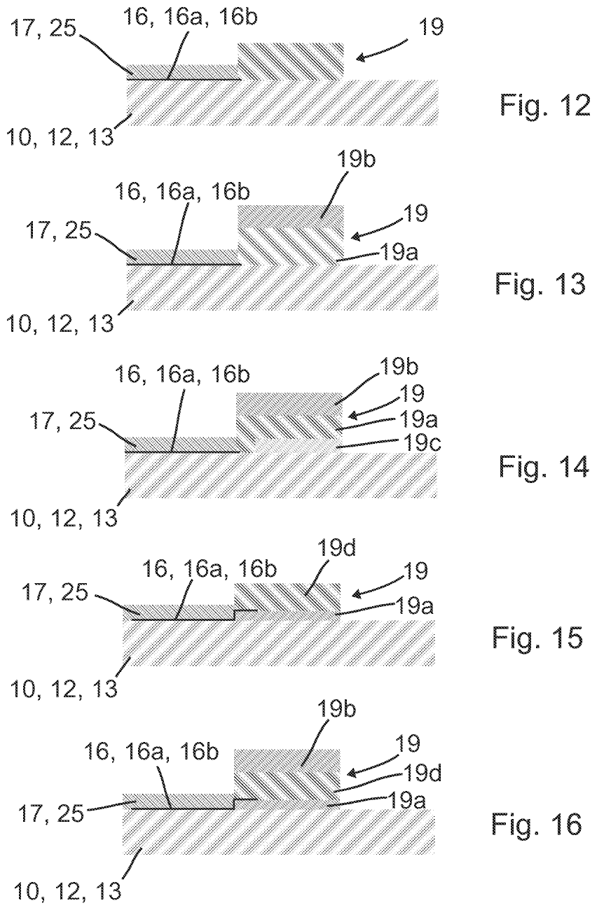

FIGS. 12 to 16 five examples of possible contacting of the active elements of the electro-optical devices of the semiconductor devices in purely schematic representation;

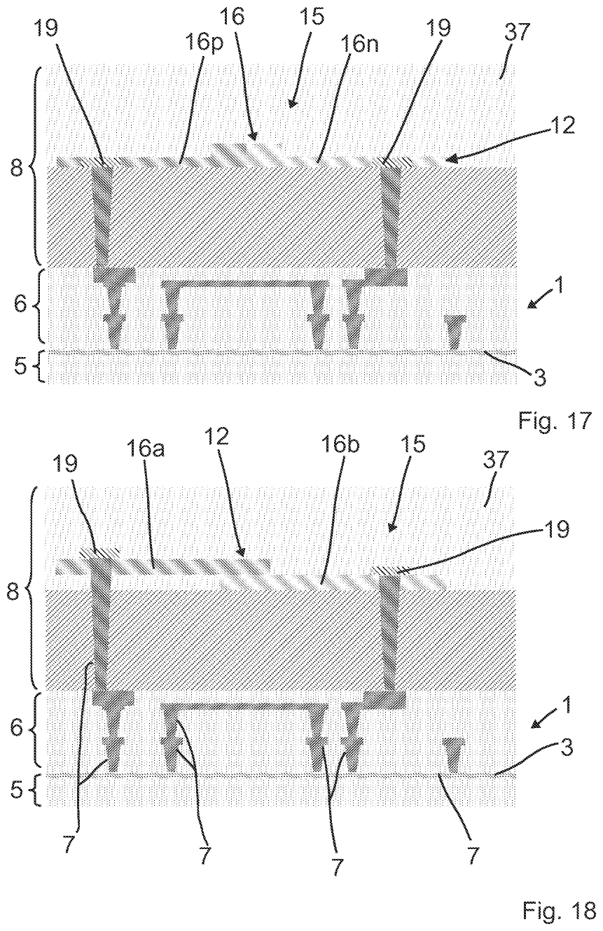

FIG. 17 a partial section through a ninth embodiment of a semiconductor device according to the invention in purely schematic representation;

FIG. 18 a partial section through a tenth embodiment of a semiconductor device according to the invention in purely schematic representation;

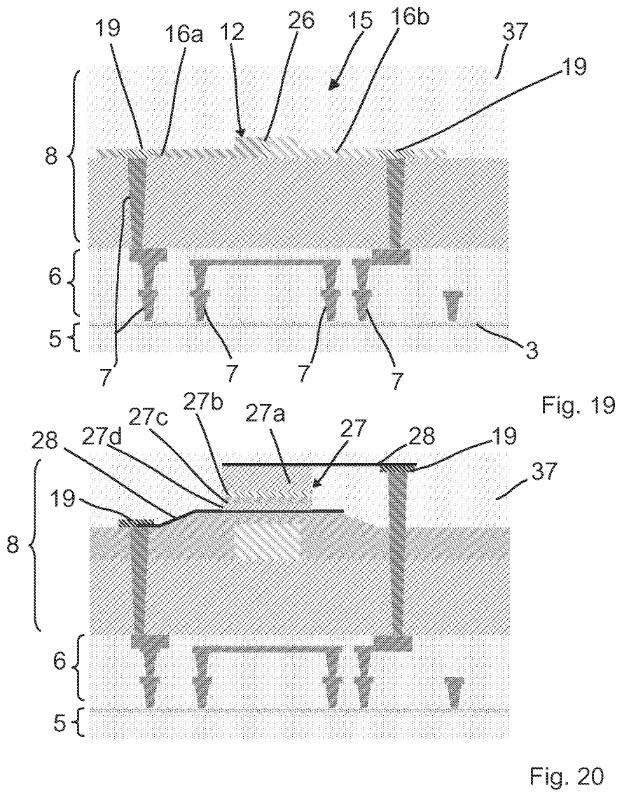

FIG. 19 a partial section through an eleventh embodiment of a semiconductor device according to the invention in purely schematic representation;

FIG. 20 a partial section through a twelfth embodiment of a semiconductor device according to the invention in purely schematic representation;

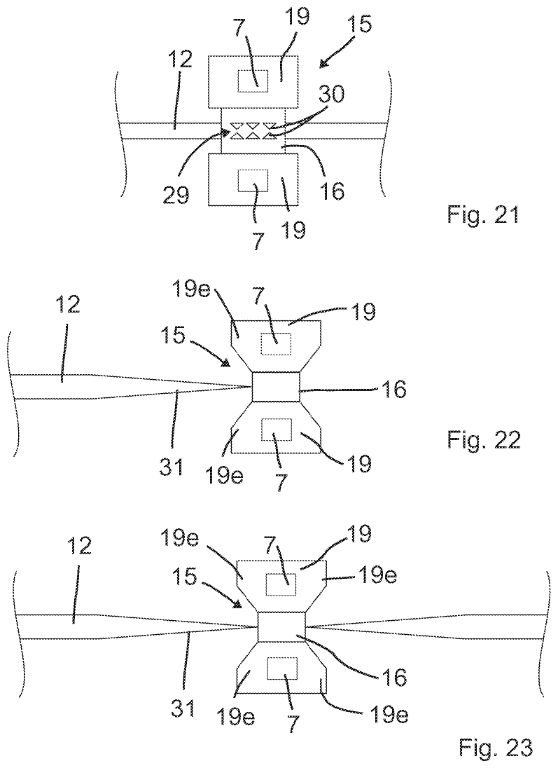

FIG. 21 a top view of a first embodiment of a photodetector with plasmonic coupling in purely schematic representation;

FIG. 22 a top view of a second embodiment of a photodetector with plasmonic coupling in purely schematic representation;

FIG. 23 a top view of an embodiment of a modulator with plasmonic coupling in purely schematic representation;

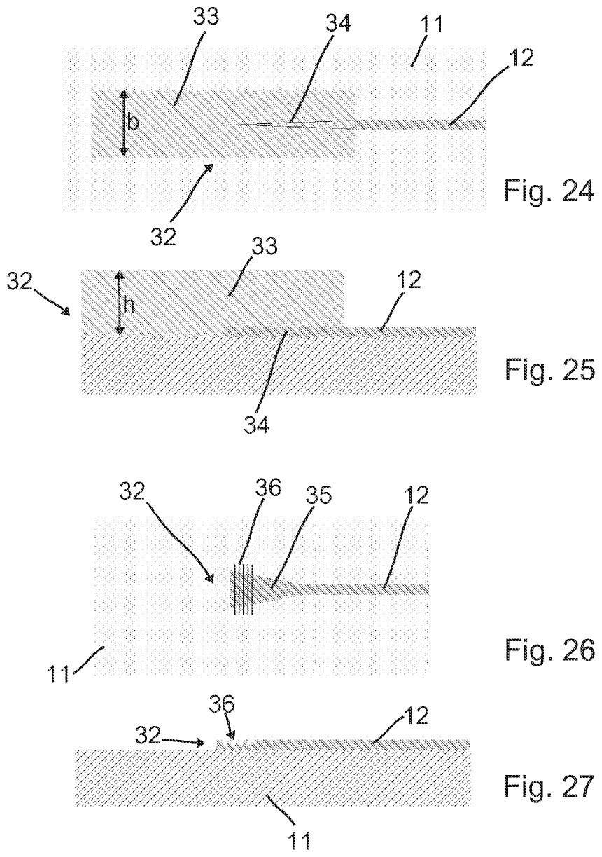

FIG. 24 a top view of an example of a side coupling device in purely schematic representation;

FIG. 25 the side coupling device of FIG. 24 in schematic sectional representation;

FIG. 26 a top view of an example of a grating coupling device in purely schematic representation;

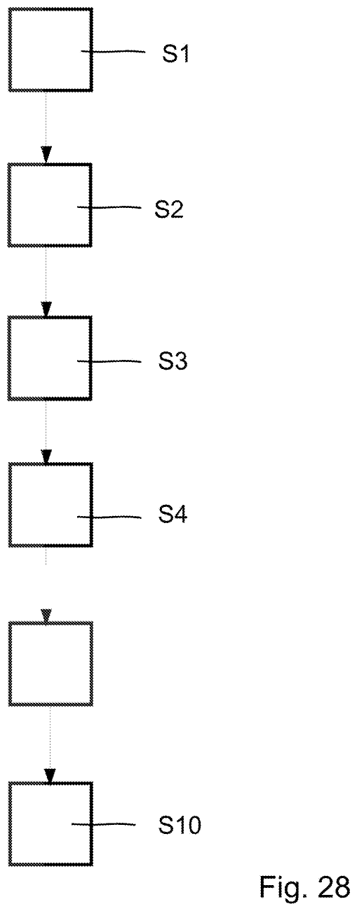

FIG. 27 the grating coupling device shown in FIG. 26 in schematic sectional representation;

FIG. 28 the steps of the method for manufacturing the device according to FIG. 1;

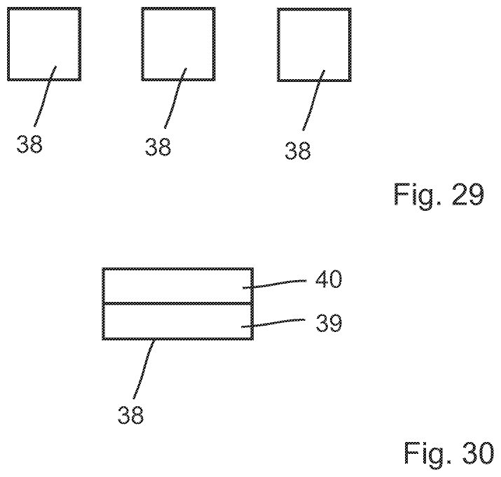

FIG. 29 a top view of three semiconductor devices according to the invention in purely schematic representation; and

FIG. 30 a purely schematic sectional representation through a semiconductor device according to the invention of FIG. 29.

In the figures, the same components or elements are marked with the same reference signs.

FIG. 1 shows in a purely schematic, highly simplified representation a top view of a semiconductor device according to the invention. This comprises a wafer 1, which can also be seen in sections in the partial sectional view according to FIG. 2, and which comprises a single-piece silicon substrate 2 and a plurality of integrated electronic components 3, which in the example shown extend in the semiconductor substrate 2. The integrated electronic components 3, which may in particular be transistors and/or resistors and/or capacitors, are indicated in the schematic FIG. 2 only in a simplified manner by a line with hatching provided with the reference sign 3. In a corresponding position in the substrate 2, a large number of integrated electronic components 3 are found in a sufficiently known manner. These can also be components of processors, such as CPUs and/or GPUs, or form such components in a likewise known manner.

The wafer 1 is a component or device from which a plurality of chips can be obtained in a manner sufficiently known from the prior art by (wafer) dicing, which is also referred to in German as “Wafer-Zerkleinern”. The dicing or fragmenting can be performed, for example, by (laser) cutting or sawing or scribing or breaking the wafer 1. Accordingly, a wafer comprises a plurality of regions, each of which forms a chip following dicing. These regions are referred to as chip regions 4.

In FIG. 1 these are indicated purely schematically with a thin line. Each chip region 4 of the wafer 1 comprises a section or partial region of the single-piece semiconductor substrate 2 and usually at least one, preferably several, integrated electronic components 3. Depending on the design of the wafer 1, which depends on the specific case of application, up to ten or even several tens, several hundreds or several thousands of integrated electronic components 3 can be provided in each chip region 4, for example. These can be arranged next to each other and/or one above the other.

The wafer 1 has a front-end-of-line (for short FEOL) 5, in which the plurality of integrated electronic components 3 are arranged, and an overlying back-end-of-line (for short BEOL) 6, in which or via which the integrated electronic components 3 of the front-end-of-line 5 are interconnected by means of different metal planes. The integrated electronic components 3 in the FEOL 5 and the associated interconnection in the BEOL 6 form integrated circuits of the wafer 1 in a sufficiently pre-known manner. A FEOL 5 is also sometimes referred to as a transistor front-end and a BEOL as a metal back-end. The metal planes comprise a plurality of interconnection elements 7, which are given in the present case by so-called VIAs, which is the abbreviation for Vertical Interconnect Access. The VIAs 7 are made of metal, for example copper, aluminium or tungsten.

The depicted semiconductor device 1 further comprises a photonic platform 8 which, as can clearly be seen in the sectional view according to FIG. 2, is located above the wafer 1 and, according to the invention, has been fabricated on its back-end-of-line 6, specifically built directly thereon. It should be noted that the chip regions 4 in FIG. 1 are indicated with a thin line, as these are located below the photonic platform 8 in the top view.

The wafer 1 is characterized by a diameter of 200 mm in the illustrated embodiment. This is also the diameter of the photonic platform 8 and the semiconductor device as a whole (cf. FIG. 1), which comprises the wafer 1 and, above the wafer 1, the photonic platform 8 fabricated thereon. The partial section according to FIG. 2 shows in the vertical direction the entire device according to FIG. 1 with the superimposed components or coats or elements thereof, but in the horizontal direction only a very small part of the device, specifically only a small part or section of one of the chip regions 4, which in turn is small in comparison to the overall extent of the device in the horizontal direction. This applies equally to the other partial sections. In the present case, the chip regions 4 are characterized in plan view by a rectangular shape in each case with an edge length of 2 mm in one direction and 3 mm in the other direction. It should be noted that these are indicated as squares in the purely schematic FIG. 1 merely for reasons of simplification.

As can be seen from FIG. 2, the photonic platform 8 provided according to the invention comprises a planarization coat 10, which has been fabricated on the side 9 of the wafer 1 facing away from the front end of line 5 and is made of a dielectric material. In the present case, the planarization coat 10 consists of silicon dioxide (SiO₂), although this is to be understood as exemplary and other materials may also be used.

In the embodiment shown, the planarization coat 10 is a coat obtained by deposition of the corresponding coating material, here SiO₂, on the side 9 of the wafer 1 facing away from the front-end-of-line 5 and subsequent planarization processing of the deposited material on the side 11 facing away from the wafer 1. The planarization coat 10 is characterized by a roughness of 0.2 nm RMS due to the processing on its side 11 facing away from the wafer 1, whereby this is to be understood as an example.

In the example shown, the planarization coat 10 extends over the entire side 9 of the wafer 1 facing away from the front-end-of-line 5. The material of the planarization coat 10 has been deposited over the entire surface of the side 9 of the wafer 1 facing away from the front-end-of-line 5. This is characterized by a diameter which at least substantially corresponds to that of the wafer 1.

The photonic platform 8 further comprises a plurality of waveguides 12 fabricated on the side 11 of the planarization coat 10 facing away from the wafer 1. Dielectrics, preferably titanium dioxide, which was also used in the illustrated embodiment, are particularly suitable as waveguide materials. Alternatively or additionally, waveguides 12 made of aluminium nitride and/or tantalum pentoxide and/or silicon nitride and/or aluminium oxide and/or silicon oxynitride and/or lithium niobate or also of semiconductors such as silicon, indium phosphide, gallium arsenide, indium gallium arsenide, aluminium gallium arsenide or dichalcogenides or chalcogenide glass or polymers such as SU8 or OrmoComp can be provided.

Typical dimensions of the waveguides 12 are a thickness in the range of 150 nm and 10 μm and in lateral extension, parallel to the wafer surface, widths between 100 nm and 10 μm. Purely by way of example, a thickness of 300 nm and a width of 1.1 μm may be mentioned. The specific dimensions of the waveguides 12 can vary. In particular, they vary in width depending on the function they perform.

In the present case, the photonic platform 8 also comprises a further planarization coat 13, which consists of the same material as the planarization coat 10, i.e. in the present case also of SiO₂. The further planarization coat 13 is characterized on its side 14 facing away from the wafer 1 by a roughness corresponding to that of the planarization coat 10. It should be emphasized that the planarization coat 10 and the further planarization coat 13—as in the present case—can be characterized by the same material, the same extent and the same roughness on their sides 11 and 14, respectively, facing away from the wafer 1, but this is not necessary and is therefore not to be understood as restrictive.

The photonic platform 8 also comprises a plurality of electro-optical devices 15, which may in particular be photodetectors and/or modulators. In the illustrated embodiment, the photonic platform 8 comprises both a plurality of photodetectors 15 and a plurality of modulators 15.

FIG. 2 shows an example of one of the electro-optical devices, specifically a photodetector 15, schematically. FIG. 3 shows—again only schematically—a top view of a section of the device of FIG. 1, specifically of the photodetector 15 of FIG. 2.

FIGS. 4 and 5 show exemplary partial sections through further embodiments of semiconductor devices according to the invention, which may correspond in plan view to that of FIG. 1, and in which in each case photodetector 15 and underlying waveguide 12 can be seen, whereby in each case the photodetector 15 and/or the waveguide 12 is embodied alternatively to that of FIG. 2. It should be noted that the schematic representation from FIG. 3 also corresponds to the detectors 15 from FIGS. 4 and 5, with the proviso that only the upper, narrow part of the waveguides with a T-shaped cross-section (cf. FIGS. 4 and 5) is shown.

FIGS. 6 and 7 show partial sections through further embodiments of semiconductor devices according to the invention. Here, photodetectors 15 are also provided as electro-optical devices, differing in structure from those of FIGS. 2, 4 and 5.

FIGS. 8, 10 and 11 show partial sections through further embodiments of semiconductor devices according to the invention, in each of which an electro-optical device embodied as a modulator 15 can be seen. FIG. 9 shows a top view of the modulator 15 of FIG. 8.

The photodetectors 15 according to FIGS. 2 and 4 to 7 each comprise an active element 16 made of a material that absorbs electromagnetic radiation of at least one wavelength, preferably of at least one wavelength range, and generates an electrical photosignal as a result of the absorption. In the examples of FIGS. 2 and 4 to 7, the active elements 16 of the photodetectors 15 are each given by a graphene film 16. Graphene may also change its refractive index (refractivity and/or absorption) as a function of a voltage and/or charge and/or an electric field. It is also possible that the active elements 16 are given by films comprising or consisting of at least one other material, for example films comprising or consisting of a dichalcogenide-graphene heterostructure consisting of at least one layer of graphene and at least one layer of a dichalcogenide, or films comprising at least one layer of boron nitride and at least one layer of graphene. There are different chalcogenides, here transition metal dichalcogenides as two-dimensional materials such as MoS2, or WSe2 are particularly suitable.

As a comparison shows, the arrangements shown in FIGS. 2 and 4 differ solely in the shape of the waveguide 12. Whereas FIG. 2 shows a strip waveguide 12 with a rectangular cross-section, FIG. 4—just like FIG. 5—shows a ridge waveguide 12 with a T-shaped cross-section with a first, upper waveguide segment 12a with a narrower rectangular cross-section and a second, lower waveguide segment 12b with a significantly wider rectangular cross-section. The example of FIG. 5 differs from that of FIG. 4 only in that no further planarization coat 13 is provided here. It should be noted that the waveguide 12 in the embodiment according to FIG. 2 could alternatively be embodied, for example, as a so-called slot waveguide with two waveguide segments spaced apart from each other to form a slot or gap.

If a waveguide 12 comprises more than one segment 12a, 12b, it can apply that all segments are made of the same material, as is the case here. However, this need not necessarily apply; the segments may also comprise different materials or consist of different materials.

In the examples shown in FIGS. 2, 4 and 5, the graphene film 16 of the respective electro-optical device 15 extends above a longitudinal section of the waveguide 12 visible in the figures in each case. This can also be readily seen from the top view shown in FIG. 3. In the examples according to FIGS. 2 and 4, the graphene film or one graphene film 16, 16a is in each case fabricated on or provided on the side 14 of the further planarization coat 13 facing away from the wafer 1. As can be seen, the graphene film 16 extends here in each case in the region of the trapezoidal section of the further planarization coat 13 on the latter, in particular due to the resist planarization. In the example shown in FIG. 5, the graphene film 16 is located directly on the waveguide 12.

FIGS. 6 and 7 show examples in which, in deviation from FIGS. 2, 4 and 5, the graphene film 16 extends not above but inside (FIG. 6) or below (FIG. 7) the respective waveguide 12. As far as the shape of the waveguides 12 is concerned, these are again formed as ridge waveguides 12 with a T-shaped cross-section.

Thereby, the waveguide 12 of the example of FIG. 6 comprises a first, upper waveguide segment 12a, a middle 12b and lower waveguide segment 12c. All of the waveguide segments 12a, 12b, 12c have a rectangular cross-section, with the middle and lower segments 12b, 12c being noticeably wider. The middle waveguide segment 12b is provided on the graphene film 16 and serves both as a passivation coat for it and as the waveguide segment 12b (may also be referred to as a waveguide slab). In the present case, the segment 12b also serving as a passivation coat is made of aluminium oxide. Alternatively or additionally, it may also comprise or consist of dichalcogenides and/or dichalcogenide heterostructures and/or SiO₂ and/or boron nitride. The two further segments 12a, 12c can, for example, also consist of or comprise aluminium oxide or also titanium dioxide.

The example in FIG. 7 differs from that in FIG. 6 in that there is no lower waveguide segment 12c. The graphene film 16 is arranged here directly on the side 11 of the planarization coat 10 facing away from the wafer 5.

In particular in the case of an electro-optical device embodied as a photodetector 15, two gate electrodes can also be assigned to the active element 16. These are then preferably embodied and arranged in such a way that the charge carrier concentration in the active element, in this case graphene film 16, can be adjusted via them and thus, for example, a pn-junction can be obtained. The gate electrodes can, for example, be arranged above the graphene film 16 and electrically insulated from it via a dielectric coat.

The modulators 15 according to FIGS. 8, 10 and 11 each comprise two active elements, specifically a lower 16a and an upper 16b, which are each provided by a film 16 of graphene. It is true for the modulators 15 as well that the active elements can also be embodied differently, for example as films comprising or consisting of at least one other material. The two graphene films 16a, 16b extend at a distance from each other and are not in electrical contact with each other. Rather, they are electrically insulated from each other by an intermediate coat 17 of a dielectric material, preferably an oxide or nitride, presently aluminium oxide. The dielectric coat 17 also serves as a passivation and as an etching protection or stop. As comparison of FIGS. 2 and 6 shows, the arrangements are identical except that the modulator 15 of FIG. 8 comprises a second active element 16b and that the additional dielectric coat 17 is provided.

The two graphene films 16a, 16b are arranged offset from each other such that they overlie or overlap (without touching) each other in sections. In the overlapping region, it further applies that the two graphene films 16a, 16b or the corresponding section thereof extend at least substantially parallel to each other. It should be noted that, alternatively to the modulator 15 comprising two active elements 16a, 16b, an electrode made of an electrically conductive material, for example copper or aluminium, may be provided instead of one of the active elements.

In the example shown in FIG. 8, the lower graphene film 16a—just like the single graphene film 16 of the detector of FIGS. 2 and 4—is provided on the side 14 of the further planarization coat 13, again in the region of the trapezoidal section above the waveguide 12. The second, upper graphene film extends on the side 18 of the dielectric coat 17 facing away from the wafer 5.

In analogy to the various examples from FIGS. 2, 4 and 5, the examples from FIGS. 8, 10 and 11 also differ essentially in that the waveguide 12 is characterized by a different shape and there is no second planarization coat 13, here neither in FIG. 10 nor in FIG. 11. While the example of FIG. 8 comprises a strip waveguide 12, those according to FIGS. 10 and 11 each comprise a ridge waveguide 12 having a T-shaped cross-section or profile. The waveguide in FIG. 10 comprises four waveguide segments 12a, 12b, 12c, 12d, when viewed in cross-section, and the waveguide in FIG. 11 comprises three segments 12a, 12b, 12c. All segments 12a to 12d have a rectangular cross-section, although, as can be seen from the figures, the upper segment 12a—in analogy to FIGS. 4 and 5—has a significantly smaller width than the underlying segments 12b, 12c and, in the case of FIG. 11, 12d. The two or three lower segments 12a, 12b, 12c are each characterized by the same width in the examples shown. Segment 12d of waveguide 12 of FIG. 10 may also be considered and referred to as the waveguide base.

In the example of FIG. 11, the lower graphene film 16a extends between the single planarization coat 10 here and the segment 12c of the ridge waveguide 12 lying there above, and the upper graphene film 16b extends between the segments 12b and 12c. The upper graphene film 16b thus extends within the waveguide 12. The lower graphene film 16a was fabricated on or provided on the side 11 of the planarization coat facing away from the wafer 5, and the upper graphene film 16b was fabricated on the segment 12c.

Each of the active elements 16, 16a, 16b of all detectors 15 and modulators 15 of the photonic platform 8 are arranged relative to the respective waveguide 12 identifiable in the figures and associated with them in such a way that they are exposed, at least in sections, to the evanescent field of electromagnetic radiation guided by the respective waveguide 12. Preferably, at least a section of the respective active element 16, 16a, 16b extends at a distance less than or equal to 50 nm, preferably less than or equal to 30 nm from the respective waveguide 12. As can be seen, for example, in FIG. 2, the further planarization coat 13 between the waveguide 12 and the graphene film 16 is correspondingly thin or “thinned out” with respect to its thickness in the remaining region.

Each of the electro-optical devices, specifically both each photodetector 15 and each modulator 15, in the illustrated embodiments is further electrically conductively connected to at least one of the integrated electronic components 3 of the front-end-of-line 5 of the respective wafer 1. As can be seen in the schematic sectional representations according to FIGS. 2 to 4 as well as 8, 10 and 11, the connection is realized via the VIAs 7 of the back-end-of-line 6 of the wafer 1 as well as further VIAs 7 extending through the planarization coat 10 and possibly further coats or elements.

Specifically, in the detectors 15, the respective graphene film 16 is electrically conductively connected at opposite end regions via contacts or contact elements 19 to the upper end of VIAs 7, which extend through the planarization coat 10 and possibly further coats or elements to the back-end-of-line 6 of the wafer 1. In the top view from FIG. 3, the VIAs 7 connected to the contact elements 19, which lie below the former, are indicated with a thin line.

In the modulators 15, each of the two graphene films 16a, 16b is connected to a contact element 19 at one end region and to a VIA 7 thereabove.

The contacting of an active element, presently graphene film 16, 16a, 16b of an electro-optical device 15 with a contact element 19 can in principle be designed in different ways. FIGS. 12 to 16 show five different possibilities by way of example.

According to the option shown in FIG. 12, an end region of the graphene film 16, 16a, 16b is in contact with a section of the underside of the contact element 19. Here, the contact element 19 is expediently made of a metal optimized for graphene, for example nickel and/or titanium and/or aluminium and/or copper and/or chromium and/or palladium and/or platinum and/or gold and/or silver.

The example shown in FIG. 13 differs from the arrangement according to FIG. 10 only in that the contact element 19 comprises not only one, but two metal layers 19a, 19b, whereby a better performance for a further connection can be achieved, since the upper layer 19b can consist of a metal optimized for a further connection. The lower layer 19a, which is in contact with the graphene film 16, 16a, 16b, expediently again consists of a metal optimized for graphene. Preferably, layer 19a consists of nickel and layer 19b consists of aluminium, or layer 19a consists of titanium and layer 19b consists of aluminium. Other combinations of nickel and/or titanium and/or aluminium and/or copper and/or chromium and/or palladium and/or platinum and/or gold and/or silver are also possible, both for active elements comprising or consisting of graphene and comprising or consisting of other electro-optically active materials.

In the example shown in FIG. 14, the contact element 19 also comprises a third, lower metal layer 19c which serves as a bonding agent. This layer 19c may, for example, consist of titanium or chromium or aluminium oxide. The layer 19a consists of, for example, nickel and/or titanium and/or aluminium and/or copper and/or chromium and/or palladium and/or platinum and/or gold and/or silver. The layer 19b may also consist of one of these metals or a combination thereof.

In the embodiments according to FIGS. 15 and 16, an end region of the active element, in this case graphene film 16, 16a, 16b, extends between a first, lower metal layer 19a optimized for graphene and a second, upper metal layer 19d of the contact element 19, which is also optimized for graphene. For this purpose, the end region of the active element 16 is characterized by an S-shaped cross section. The two layers 19a and 19d preferably consist of palladium or nickel or gold or platinum or a combination of nickel and/or titanium and/or aluminium and/or copper and/or chromium and/or palladium and/or platinum and/or gold and/or silver.

The example of FIG. 16 differs from that of FIG. 15 only in that, by analogy with FIG. 14, the contact element 19 comprises a third metal layer 19b which is optimized for further connection and, for example, like the layer 19b of FIG. 13, may consist of aluminium.

For all contacting examples, the graphene film 16 can be covered by the contact element 19 or a layer 19a to 19d thereof, so that the current passes in a vertical transition from the contact element 19 or a layer thereof into the graphene (top contact), or the graphene film 16 can also end at the edge of the contact element 19 or a layer 19a-19d thereof, so that the current passes laterally into the graphene film 16 (side contact). For example, the arrangement according to FIG. 13 can also be embodied as a top contact.

A passivation coat 25 is preferably provided above each active element, i.e. preferably above each of the graphene films 16. This can only be seen in FIGS. 12 to 16, which each show a section of a graphene film 16, 16a, 16b in an enlarged view.

In the present case, the passivation coat 25 is made of aluminium oxide. Alternatively or in addition thereto, such passivation coat 25 may also comprise or consist of dichalcogenides and/or dichalcogenide heterostructures and/or SiO₂ and/or boron nitride. The passivation coat 25 passivates the active elements, in this case the graphene films, and at the same time serves as an etch stop layer, so that selective etching of the contact elements 19 for connection to the VIAs 7 is possible.

It should be noted that in the case of a modulator 15, the dielectric coat 17 provided between the two active elements 16a, 16b (cf. FIG. 8) can already serve to passivate the lower element 16b. In this case, a passivation coat 25 does not have to be assigned to it as well.

Furthermore, it should be noted that even if in the examples according to FIGS. 12 to 16 the active elements 16, 16a, 16b are given by graphene films, the embodiments shown are by no means limited to this material. Also for active elements 16 comprising or consisting of one or more other materials, the contacting can be designed accordingly.

Embodiments of photodetectors 15 or modulators 15 with active elements without graphene are shown in FIGS. 17 to 20.

In this regard, the embodiment of FIG. 17 comprises an active element 16 formed by a coat of polycrystalline silicon which also forms the waveguide 12. As can be seen, the silicon coat 16 has the shape of a ridge waveguide with a T-shaped cross-section. In the present case, the silicon coat forming the active element 16 and the waveguide 12 has two doped regions, namely a p-doped region 16p and an n-doped region 16n. It should be noted that, alternatively, a pin-transition could also be present, i.e. an undoped region could also lie between the p-doped and the n-doped regions. The silicon coat 6, like the active elements 16 of the examples of FIGS. 2 and 4 to 7, is connected to two contact elements 19. Depending on the polarity of an applied voltage, the charge carrier concentration in the barrier coat changes and thus also the absorption and the refractive index of the waveguide 12. It can also be said that the waveguide 12 is designed as a diode here in order to obtain a modulator.

FIG. 18 shows another example of a silicon modulator, also known as SISCAP (see also the publication “An efficient MOS-capacitor based silicon modulator and CMOS drivers for optical transmitters,” by M. Webster et el, 11th International Conference on Group IV Photonics (GFP), Paris, 2014, pp. 1-2. doi: 10.1109/Group4.2014.6961998). Here, two active elements 16a, 16b are provided, each formed by a silicon coat, preferably of crystalline silicon or polysilicon or amorphous silicon. Here, the active element 16a is p-doped and the element 16b is n-doped. The active elements 16a, 16b are further arranged offset from one another in such a way that they lie above one another in an overlapping region, this in analogy with the active elements 16 of the examples from FIGS. 8, 10 and 11. The overlapping region here forms the waveguide 12. The charge carrier concentration can be adjusted in this region and thus the optical properties of the waveguide 12.

FIG. 19 shows another example of a silicon modulator 15, which also comprises two active elements 16a, 16b formed by silicon coats that are p- and n-doped, respectively. These are adjacent to each other in a plane, and an element of electro-optical polymer 26 is provided between them. The two active elements 16a, 16b and the element 29 of an electro-optical polymer form a ridge waveguide 12 with a gap—formed by the element 26. In other words, the sidewalls of the gap serve here as electrodes of a capacitance. The electric field in the gap affects the optical properties of the polymer and enables modulation of an optical signal.

FIG. 20 shows an example of a modulator with a diode 27 made of compound semiconductors. The diode 27 consists of coats 27a to 27d of different composition, for example InGaAsP, in order to create a pn-junction and two contact regions. The contact regions are connected to the contact elements 19 and thus to integrated electronic components 4 by means of electrodes 28.

The electro-optical device or at least one electro-optical device—both in the case of a modulator 15 and in the case of a detector 15—may further be designed or fabricated as such with plasmonic coupling.

Corresponding examples can be found—in each case in purely schematic view—in FIGS. 21 to 23.

In this regard, FIG. 21 shows an example of a photodetector 15 in which a plasmonic structure 29 consisting of or comprising a plasmonically active material is provided, in concrete terms on the active element 16. In the example, the plasmonic structure 29 comprises three pairs of plasmonic elements 30 arranged next to one another and consisting of or comprising the plasmonically active material. Presently, the plasmonic elements consist of gold. Other suitable examples of materials include silver and/or aluminium and/or copper. The plasmonic elements 30 form quasi antennas on the waveguide 12 to increase absorption (see also Ma et al., “Plasmonically Enhanced Graphene Photodetector Featuring 100 Gbit/s Data Reception, High Responsivity, and Compact Size,” ACS Photonics 2019, 6, pages 154 to 161 (2018)). Such a plasmonic structure may be or become provided, for example, on the active element 16 of an arrangement according to FIG. 2, 4, or 5.

FIG. 22 shows an example of a photodetector 15 in which no waveguide 12 or section of such a waveguide is provided below or above the active element 16, but in which a waveguide 12 is preferably provided in a plane with the active element 16 and laterally thereto, which waveguide 12 has a section 31 tapering in a V-shape in the direction of the active element 16. The section 31 tapers to a point which extends to the left side of the active element 16, for example graphene film, in FIG. 22. As can be seen, the contact elements 19 here comprise sections 19e which taper in the opposite direction, that is in the direction away from the active element 16. In a manner of speaking, the contact elements 19 follow the tapering end section 31 of the waveguide 12 in sections, which enables plasmonic coupling.

FIG. 23 shows an analog modulator 15 with plasmonic coupling. As can be seen, waveguide sections 31 tapering in a V-shape in the direction of the active element 16 are provided on two opposite sides of the active element 16, e.g. graphene film, and sections 19e of the contact elements 19 tapering in the opposite direction are provided for both associated waveguide sections 31 and 19e. Thus, coupling of an optical mode to a plasmonic mode and back to an optical mode is possible here. In particular, in this embodiment, it may further be provided that the active element comprises or consists of at least one electro-optical polymer (see also the publication “Silicon-Organic Hybrid (SOH) and Plasmonic-Organic Hybrid (POH) Integration”, by Koos et al, Journal of Lightwave Technology, Vol. 34, No. 2, 2016).

The photonic platform 8 fabricated on the wafer 1 of a semiconductor device according to the invention will generally comprise a very large number of electro-optical devices 15, which may be given in particular by photodetectors and/or modulators. This is also the case in the illustrated embodiment. In particular, each section of the photonic platform 8 extending above a chip region 4 of the wafer 1 will already comprise a plurality of electro-optical devices 15 and a plurality of waveguides 12. For example, tens, hundreds, or even thousands of electro-optical devices 15 and/or waveguides 12 may be provided on each section of the photonic platform 8 extending above a chip region 4. The number can be selected in each case for the specific application.

In the illustrated embodiments of semiconductor devices according to the invention, all electro-optical devices 15 and waveguides 12 of the photonic platform 8 are structurally identical. In this respect, the conformity enables a particularly simple, rapid fabrication. It should be emphasized, however, that it is of course also possible for a semiconductor device according to the invention to comprise different ones of the examples shown in FIGS. 2, 4 to 8, 10, 11, and/or 17 to 23, for example both detectors 15 with underlying waveguides 12 according to FIG. 2 and modulators 15 and waveguides 12 according to FIG. 8. There may also be more than two different ones of the examples according to FIGS. 2, 4 to 8, 10, 11, and/or 17 to 23, for example also all of them one or more times, respectively.

In order to be able to realize arrangements with a further planarization coat 13 (cf. e.g. FIGS. 2, 4 and 8) as well as arrangements without such a coat (cf. e.g. FIGS. 5, 10 and 11) in a photonic platform 8, it can be provided that after the preferably two-dimensional fabrication of the further planarization coat 13, this coat is removed again in sections, e.g. by lithography and subsequent etching, wherever an arrangement without a further planarization coat is desired. For other coats, which are only desired in some places but not everywhere, a completely analogous procedure can be or has been used.

The active element(s) 16, 16a, 16b of each electro-optical device may be electrically conductively connected to one or, in the case of the detectors, two contact elements 19 in any of the ways shown in FIGS. 12 to 16. It is possible that all active elements 16, 16a, 16b of a semiconductor device according to the invention are contacted with contact elements 19 in the same way. Alternatively, it is of course also possible that different active elements 16 of a device are contacted in different ways.

In FIGS. 3 and 9, in addition to the active element(s) 16, 16a, 16b, the waveguides 12 and contact elements 19, coupling devices 32 of the photonic platform 8 are schematically indicated, which serve to couple light into or out of the waveguide 12. One of the coupling devices 32 is arranged here at each of the opposite ends of the respective waveguide 12. In the present case, the coupling devices 32 are each designed as side or grating coupling devices. FIGS. 24 to 27 show purely schematic representations of examples of such. FIGS. 24 and 25 show a side coupling device 32 in plan view and in section, and FIGS. 26 and 27 show a grating coupling device 32 in plan view and in section.

It may be that a coupling device 32 is or two coupling devices 32 are associated with several, possibly also to each of the waveguides 12 of the photonic platform 8. In particular, two coupling devices 32 have been or are associated with a waveguide 12 in the case where light is to be coupled in and out. However, it is also possible that only a possibly initial coupling is desired. Then one coupling device 32 can be sufficient.

The example of the side coupling device 32 shown in FIGS. 24 and 25 comprises a side coupling element 33 consisting preferably of resins or resin-containing materials, in particular SU8, or/and silicon nitride, or/and silicon oxynitride or dielectrics, whose refractive index lies between that of the waveguide 12 (in particular n=2.4) and that of the element 33 (SU8 n=1.56) serving as a mode field converter, such as aluminium oxide (n=1.68). As can be seen, the latter is characterized by a width b as well as a height h which exceeds the extension of the waveguide 12 in corresponding directions, in the present case corresponding to a multiple thereof in each case. The side coupling device 32 further comprises an end section 34 of the waveguide 12 extending into the side coupling element, which, as can be readily seen in FIG. 24, tapers conically towards its end. It should be noted that in FIG. 24, the outer contour of the tapered section 34 is indicated with a thin line, as it is obscured in plan view by a section of the element 33. The element 33 causes the mode field to be matched from the diameter of an optical fiber (for example, 5 μm to 15 μm in diameter) to the size of the waveguide 12 (for example, 300 nm in height, 1.1 μm in width). The tapered tip 34 of the waveguide 12 causes an adiabatic adjustment of the effective refractive index in the region of the mode field, so that the optical mode is increasingly transferred from the coupling structure into the waveguide 12.

As can be seen from the top view in FIG. 26, the grating coupling device 32 is formed by an end section 35 of the waveguide 12 which widens conically towards the end and, as it is also well shown in the sectional view in FIG. 27, has a grating structure 36 on its side facing away from the wafer 5. This widening adapts the dimension of the waveguide 12 (e.g. 300 nm height, 1.1 μm width) to the diameter of the mode field in an optical fiber (e.g. 5 μm to 15 μm) and thus increases the coupling efficiency. In the top view according to FIG. 26, the grating structure 36 is only simplified by several parallel lines. The incident light is diffracted by the grating-like arrangement of refractive index steps. The dimensions of the grating are conveniently calculated so that at a given angle of incidence the first diffraction order is located in the waveguide 12 and thus the light is coupled into the waveguide 12.

The coupling devices 32 lie in one plane with the respective waveguide 12, i.e. they are located on the side 11 of the planarization coat 10 facing away from the wafer 5.

The waveguides 12, which are shown only in sections in FIGS. 21 to 23 comprising partial views, can also be provided with a coupling device 32 at their ends which cannot be seen.

In addition to the electro-optical devices 15, the photonic platform 8 may also include one or more optical devices. These may be, for example, one or more interferometers, such as Mach-Zehnder interferometers, and/or MMIs and/or directional couplers and/or ring resonators and/or polarization converters and/or splitters. The optical devices are typically formed by multiple sections of waveguides 12, which are then arranged accordingly. In particular, they constitute passive structures of waveguides 12 or of longitudinal waveguide sections. A section, in particular a section in the longitudinal direction, i.e. a longitudinal section of a waveguide 12, for example the waveguides 12 to be seen in FIGS. 2, 4 to 11, can in each case be a component of such an optical device, specifically a section which lies in front of or behind the electro-optical device 15 in the direction oriented perpendicularly to the drawing plane.

It is also possible for the photonic platform 8 to include one or more thermo-optical devices. For example, one such device includes a heating element and a longitudinal section of a waveguide 12, the heating element being arranged relative to the waveguide section such that it can heat the waveguide section. Heating the waveguide 12 by means of the heating element can change the refractive index of the waveguide 12 in the longitudinal section. This effect can be used, for example, for phase matching. A thermo-optical device may also be associated with or form part of an interferometer of the photonic platform. For example, a longitudinal section of the waveguide 12 seen in FIGS. 2, 4 to 11 can each be part of a thermo-optical device, again a section that lies in front of or behind the electro-optical device 15 in a direction oriented perpendicularly to the drawing plane.

The photonic platform 8 further comprises a passivation coat 37 which extends above the electro-optical devices 15 and preferably forms the upper finish of the photonic platform 8 and the semiconductor device (cf. FIG. 1). The passivation 37 simultaneously constitutes a cladding. It should be noted that the passivation coat 37 is not shown in the views according to FIGS. 3 and 9, but only the underlying devices 15.

To obtain the semiconductor device shown in FIG. 1, in a first step S1 (cf. FIG. 28) the wafer 1 is provided with the integrated circuits comprising the integrated electronic components 3 and the metallization including the VIAs 7. The wafer 1 may be any wafer 1 of conventional type obtained by a previously known manufacturing process.

Then, the photonic platform 8 is fabricated on the BEOL 6 of the wafer 1.

Specifically, in a second step S2, the planarization coat 10 is fabricated on the back-end-of-line 6 of the wafer 1. For this purpose, a coating material, in this case silicon dioxide (SiO₂), is applied, which can be done for example by chemical vapor deposition, such as low-pressure chemical vapor deposition (LPCVD) or plasma-enhanced chemical vapor deposition (PECVD), or physical vapor deposition or also by spin-coating with spin-on-glass. In the present case, PECVD is used. After the coating material has been deposited, the side of the coating facing away from wafer 5 is subjected to a planarization treatment (step S3), in this case a resist planarization, whereby a side 11 facing away from wafer 5 is obtained with a roughness of 0.2 nm RMS.

Resist planarization includes a single or repeated spin-on-glass deposition and subsequent etching, in this case reactive ion etching (RIE). The spin-on-glass coat partially compensates for height differences, i.e. valleys of the topology have a higher coat thickness after spin-on-glass coating than adjacent elevations. If the entire spin-on-glass coat is etched after spin-on-glass coating, for example by RIE, the height difference has been reduced due to the planarizing effect of the spin-on-glass coat. By repetition, the height difference can be further reduced until the desired roughness is obtained.

It should be noted that a side 11 of the planarization coat 10 facing away from the wafer 5 of a corresponding low roughness can alternatively be obtained, for example, via chemical mechanical polishing (CMP).

In the next step S4, the waveguides are fabricated. For this purpose, waveguide material, in this case titanium dioxide (TiO₂), is deposited, in particular over the entire surface 11 of the resulting planarization coat 10. As with the planarization coat, the material can be deposited by PVD or CVD, in particular PECVD or LPCVD, or by spin-coating. An atomic layer deposition (ALD) can also be carried out or a transfer print process. In analogy to the planarization coat 10, LPCVD is used. Lithography and structuring, in particular by means of reactive ion etching (RIE), are carried out to obtain the individual waveguides 12.

To obtain the strip waveguides 12 (see, for example, FIGS. 3 and 8), the waveguide material is completely removed wherever no strip waveguide 12 is to remain, in other words etched down to the underlying coat 10.

The coupling devices 32 including their waveguide ends 34, 35 belong (cf. FIGS. 3, 9 and 24 to 27) are fabricated in the present case together with the ridge or strip waveguides 12, wherein for the case of ridge waveguides 12 the lateral extension of the waveguide 12 in the region of the coupling point can be removed dry-chemically in a separate etching step. Waveguides 12 consisting of superimposed coats can be structured with the uppermost coat 12a after completion of the coat structure, and for the case of ridge waveguides 12, the lateral extension of the waveguide in the region of the coupling point can be removed dry-chemically in a separate etching step. In all cases, mode converters can be defined between ridge and strip waveguides 12, and sections of the ridge waveguides 12 can be formed as strip waveguides 12 using lithography and RIE.

Grating couplers 32 with grating structures 36 can be lithographically defined and dry chemically structured.

For side coupling elements (mode converters) 33, dielectrics and/or semiconductors and/or resins and/or polymers are deposited in one or more layers and structured by means of lithography or/and RIE.

In a next step S5, the further planarization coat 13 is fabricated on the waveguides 12 and the side 11 of the planarization coat 10. In the present case, this is obtained in a completely analogous manner to the planarization coat 10 by deposition using PECVD and resist planarization. As a result of the resist planarization, the cross-section of the further planarization coat 13 above the waveguide 12 is trapezoidal (see FIG. 2).

Also with regard to the further planarization coat 13, it applies that alternatively to LPCVD and CMP, other of the above-mentioned processes can be used and another planarization treatment, such as CMP, and/or further planarization is possible, as described above for the planarization coat 10. If CMP is used, a flat surface is generally obtained, i.e., there is then no trapezoidal section above the waveguide 12 as seen in FIG. 2 (and also FIGS. 4 and 9, for example).

The planarization coat 10 and further planarization coat 13 can comprise one or more cover layers which are preferably provided on the surface subjected to the planarization treatment and which can be, for example, dichalcogenide layers or dichalcogenide heterostructures or also boron nitride layers. These materials are preferably deposited or transferred without the need for further chemical-mechanical polishing or further resist planarization, although it is not excluded that this is repeated again.

For the sake of completeness, it should be noted that in the event that a semiconductor device according to the invention is also to have regions without a further planarization coat 13, for example also regions in which the structure corresponds to that according to FIG. 5, 10 or 11, the further planarization coat 13 (and any coats located thereon) is subsequently partially removed again, in particular by lithography and etching.

In step S6, the VIAs 7 are fabricated through the planarization coat 10 and the further planarization coat 13. In principle, this can be done in any way known from the prior art. In particular, the regions in which these are to extend are first defined preferably by lithography and dry-chemically etched by means of RIE. Then metallization is carried out and the metallized surface is structured, for example by means of CMP (Damascene process) or by means of lithography and RIE. It is possible both that the VIAs 7 are fabricated after completion of the further planarization coat 13 through both planarization coats 10, 13 or also that after completion of the first coat 10 sections of the VIAs 7 are fabricated through the first planarization coat 10 and after completion of the second planarization coat 13 sections of the VIAs 7 are fabricated through the second coat 13.

Subsequently, the electro-optical devices 15 are fabricated.

For this purpose, in step S7 the respective active elements of the detectors given by the graphene film 16 are provided on the side 14 of the further planarization coat 13 facing away from the wafer 5, for example deposited on the side 14, and then in step S8 the contact elements 19 (single or multilayer) are obtained.

The deposition of the graphene films 16 can, for example, be carried out via a transfer process as described in more detail above. Then, in particular, a graphene film fabricated on a separate substrate or a separate metal foil or a separate germanium wafer is transferred to the further planarization coat 13 in each case. It is also possible that the graphene films are fabricated directly on the further planarization coat 13. This may include, for example, material deposition.

If a transfer process is used, it is possible that the passivation coat 25 is already provided on the side of the respective graphene film 16 facing away from the wafer 5, that this layer has been deposited thereon, for example, and is then transferred with it. Alternatively, the passivation coat 25 can also be deposited after transferring or fabricating the graphene film(s) 16.

It is also possible that first a full-area graphene film and/or a full-area passivation coat is fabricated on the further planarization coat 13, which extend over the entire surface of the further planarization coat 13. In this case, further structuring is then carried out, in particular by lithography and RIE, in order to obtain the individual graphene films 16 as active elements of a plurality of electro-optical devices 16.

The contact elements 19 or their layers 19a to 19d are then fabricated, preferably by depositing one (FIG. 12) or more layers (FIGS. 13 to 16) of metal over the entire surface and then structuring by means of lithography and RIE.

In the manner described with the manufacturing sequence of first the graphene films 16 and then contact elements 19, contacting can be achieved as schematically shown in FIGS. 12 to 14.

For the contacting variants shown in FIGS. 15 and 16, only the lower metal layer 19c or 19a of the contact elements 19 is fabricated first, followed by the graphene films 16 and then the further layer 19b, 19d or the two further layers 19a, 19b or 19d, 19b. This can also be done via full-area deposition of an appropriate metal and subsequent structuring by lithography and RIE.

In a second to last step S9, the upper passivation 37 is deposited, preferably of Al₂O₃ and SiO₂. In this passivation, openings, in particular to contact elements, are then suitably fabricated by means of lithography and RIE (step S10). Preferably, openings to contact elements, which serve to connect the photonics and/or electronics to the outside, are fabricated.

By the steps described above, a semiconductor device comprising strip waveguides 12 and electro-optical devices 15 as shown in FIG. 2 can be obtained.

If a semiconductor device is to be obtained which exclusively—or also additionally—has regions which are constructed as shown in FIG. 4, i.e. which comprise ridge waveguides 12, only step S4 must be varied to the effect that the segments 12a are etched laterally only to a lesser depth so that waveguide material still remains laterally of the segments 12a and the segments 12b, 12c are obtained which the strip waveguides do not have.

To obtain the structure according to FIG. 5, only the further planarization coat 13 must be removed again in sections before the ridge waveguides 12 are fabricated. If a semiconductor device is to be obtained which does not have a further planarization coat 13 at any point, its fabrication can of course also be dispensed completely.

To obtain the example shown in FIG. 6, the lower waveguide segment 12c is first fabricated on the side of the planarization coat 10 facing away from the wafer, using the methods described above, e.g. PECVD. Then the active element, in this case the graphene film 16, and the contact elements 19 are fabricated, the order again depending on which of the contacting schemes shown in FIGS. 12 to 16 is chosen. Then the passivation coat 25 is fabricated on the graphene film 16 (shown only in FIGS. 12 to 16) and then the two segments 12b and 12a and the coat 37.

To obtain the arrangement shown in FIG. 7, a substantially analogous procedure can be followed, omitting only the step of fabricating the waveguide segment 12c and providing the graphene film 16 on the side 11 of the planarization coat 10 facing away from the wafer 5.

Also for fabricating a semiconductor device according to the invention, which comprises one or more modulators 15 as electro-optical devices, the procedure is partly different from that described above in connection with FIG. 2.

For the example according to FIG. 8, for example, up to the fabrication of the further planarization coat 13 and the VIAs 7 by the planarization coat 10 and this 13, the procedure can in principle be the same, i.e. steps S1 to S6 can be identical.

However, the fabrication of the respective modulator(s) 15 then comprises first providing the one, lower graphene film 16a as one of the two active elements on the further planarization coat 13 and producing only one contact element 19 at its one end region pointing to the left in FIG. 8. The fabrication can be carried out in the same way as described above in connection with FIG. 2 for the one graphene film 16 and the two contact elements 19.

Subsequently, the dielectric coat 17 is provided, for example by deposition preferably of aluminium oxide. It is also possible that the dielectric coat 17 is provided by a transfer process.

The second, upper graphene film 16b is then fabricated, and the second contact element 19 is fabricated at its end region pointing to the right in FIG. 6. The production can again be carried out in the same way as described above in connection with FIG. 2 for the one graphene film 16 and the two contact elements 19.

Then, steps S8 and S9 described above can follow to obtain the upper passivation 37 and the openings therein.

For the structure according to FIG. 10, steps S1 to S6 can also be carried out identically and then the further planarization coat 13 can be partially removed again. Alternatively, their production, i.e. step S5, can be omitted and only VIAs can be fabricated through the planarization coat 10 in step S6.

Then, on the side 11 of the planarization coat 10 facing away from the wafer 5, the segment 12d, i.e. the waveguide base, is fabricated by depositing an optically transparent, preferably dielectric coat or semiconductor and structuring it by means of lithography and RIE. In the present case, TiO₂ is deposited.

On the side of the waveguide base 12d facing away from the wafer 5, the lower graphene film 16a and then the contact element 19 belonging to it are fabricated, on top of this the waveguide segment 12c, above this the upper graphene film 16b with associated contact element 19, on top of this the waveguide segment 12b and on top of this the waveguide segment 12a, which is characterized by a significantly smaller width than the other segments 12b, 12c, 12d. The material for the waveguide segment 12b can be fabricated, for example, by means of ALD or by a chalcogenide coat obtained by CVD or transfer and ALD, and/or by a coat of dielectric or semiconducting material fabricated by means of PVD and structured by lithography and RIE. Subsequently, segment 12a is provided, wherein, by means of ALD and/or PVD and/or PECVD and/or LPCVD, a dielectric or semiconducting material and/or a dichalcogenide coat obtained by CVD or transfer is provided and structured using lithography and RIE.

The graphene films 16a, 16b and contact elements 19 can be fabricated in the same manner as described above in connection with FIG. 2.

In this example, the upper graphene film 16 extends within the waveguide 12.

Finally, steps S9 and S10 can be performed, again to obtain the passivation coat 37 and openings therein.

In order to obtain the arrangement according to FIG. 11, it is possible to proceed mostly in the same way as described above in connection with FIG. 10, with the only difference that the fabrication of the lowest waveguide segment 12d in FIG. 10 is omitted and the lower graphene film 16a is fabricated directly on the side 11 of the planarization coat 10.

To obtain the arrangement according to FIG. 17, the same procedure can be followed again until the completion of the planarization coat 10 (steps S1 to S3). On its side 11 facing away from the wafer 5, the silicon coat 16 is then fabricated as an active element. This may again include material deposition, such as via one of the aforementioned processes, for example a CVD or PVD process or spin-coating, and subsequent structuring (e.g. lithography and RIE) to obtain the T-shape. The obtained ridge waveguide is p-doped on its one side and n-doped on its other side to obtain the 16p and 16n regions. In this way, the pn-junction is obtained. Then the contact elements 19 can be fabricated.

For the modulator 15 shown in FIG. 18, which is designed as a so-called SISCAP, the steps S1 to S3 can again be identical and then the two silicon coats 16a and 16b, each forming an active element, are fabricated, which can also include a material deposition, for example via one of the aforementioned processes, for example a CVD or PVD process or spin-coating, and a subsequent structuring (e.g. lithography and RIE), and the associated contact elements 19 are fabricated.

For FIG. 19, it is possible to proceed in principle as for FIG. 17, with the addition of the element 26 made of an electro-optical polymer between the two elements 16a and 16b.

To obtain the modulator 15 according to FIG. 20, the steps S1 to S5 can be identical as described above in connection with FIG. 2. On the side 14 of the further planarization coat 13 facing away from the wafer 5, the first electrode 28 with associated contact element 19 can then be fabricated, then the diode 27 with coats 27a to 27d and then the second electrode 28 with associated contact element 19, whereby this can in each case include material deposition and subsequent structuring.

Finally, in all of the examples of FIGS. 17 through 20, the coat 37 may be prepared in a manner analogous to the remaining examples.

As can be seen from the above, the photonic platform 8 is fabricated directly on the BEOL 6 of the wafer 1. It can also be said to be monolithically fabricated on wafer 1, or to be a monolithic platform 8. In particular, the coats 10, 13, 37 and the waveguides 12 are fabricated directly on the wafer 1 by respectively depositing appropriate material on the BEOL 6 of the wafer 1, or on coats already fabricated thereon. There is no separate fabrication of the coats 10, 13, 37 or waveguides 12 and subsequent connection by bonding.

It should be noted that the above-described methods for manufacturing semiconductor devices according to the invention are embodiments of the method according to the invention.

After completion of a semiconductor device according to the invention, a plurality of chips with integrated photonics can be obtained from it in a simple and fast way, specifically by mere dicing, in other words fragmenting.

In the semiconductor device shown in FIG. 1, dicing can be performed, which includes, for example, (laser) cutting and/or sawing and/or breaking along the shown lines defining the chip regions 4. In principle, dicing can be performed in any manner known from the prior art, in particular as in the prior art for conventional wafers 1.

FIG. 29 shows, by way of example and purely schematically, three chips with integrated photonics obtained by such dicing in plan view. These represent embodiments of semiconductor apparatuses 38 according to the invention. Each of these semiconductor apparatuses 38 comprises a chip 39, the extent of which corresponds to a chip region 4 of the wafer 1, and a section 40 of the photonic platform 8 lying above it, the lateral extent of which due to the dicing coincides at least substantially with the lateral extent of the chip 39 lying below. The chip 39 and the above lying section 40 of the photonic platform 8 can be taken from the purely schematic sectional view shown in FIG. 30.

It should be noted that in this highly simplified illustration, only the two superimposed regions defined by the chip 39 and photonics 40 are indicated, but not coats and components thereof.

The chip 39 comprises, inter alia, a plurality of integrated electronic components 3, such as transistors and/or capacitors and/or resistors, which may be, for example, parts of a processor of the chip 39, and the section 40 of the photonic platform 8 comprises, inter alia, a plurality of electro-optical devices 15, such as may be taken in particular from FIGS. 2 to 11, and 17 to 23.

The semiconductor apparatuses 38 obtained by dicing a semiconductor device according to the invention, each of which represents a bare chip with monolithically integrated photonics, can then be inserted into packages, as is known from conventional bare chips, and used for further applications.

The photonic platform section 40 may be used, for example, to convert electrical signals from the integrated electrical components of the chip 39 into optical signals so that, for example, communication with other chips and/or other integrated electronic components 4 of the apparatus 38 may be accomplished by optical means. For this purpose, for example, light may be modulated by a modulator 15 coupled to an integrated electronic component, such as transistor 4, and the modulated light signal may be received, for example, by a photodetector 15 coupled to another integrated electronic component, such as transistor 4 of the same or a different chip.

1. Semiconductor device comprising a wafer (1) with a preferably single-piece semiconductor substrate (2), in particular silicon substrate, and at least one integrated electronic component (3) extending in and/or on the semiconductor substrate (2), the wafer (1) having a front-end-of-line (5) and a back-end-of-line (6) lying there above, the front-end-of-line (5) comprising the integrated electronic component or at least one of the integrated electronic components (3), and a photonic platform (8) fabricated on the side (9) of the wafer (1) facing away from the front-end-of-line (5), which photonic platform (8) comprises at least one waveguide (12) and at least one electro-optical device (15), in particular at least one photodetector and/or at least one electro-optical modulator, wherein the electro-optical device (15) or at least one of the electro-optical devices (15) of the photonic platform (8) is connected to the integrated electronic component (3) or at least one of the integrated electronic components (3) of the wafer (1).

2. Semiconductor device according to claim 1, wherein the back-end-of-line (6) of the wafer (1) and the photonic platform (8) comprise interconnection elements (7) through which the integrated electronic component (3) or at least one of the integrated electronic components (3) of the wafer (1) is connected to the electro-optical device (15) or at least one of the electro-optical devices (15) of the photonic platform (8).

3. Semiconductor device according to claim 1, wherein the photonic platform (8) comprises material deposited on the side (9) of the wafer (1) facing away from the front-end-of-line (5).

4. Semiconductor device according to claim 1, wherein the photonic platform (8) comprises a planarization coat (10) of a dielectric material fabricated in particular on the side (9) of the wafer (1) facing away from the front-end-of-line (5), and preferably the waveguide or at least one of the waveguides is fabricated on the side (11) of the planarization coat (12) facing away from the wafer (1).

5. Semiconductor device according to claim 3, wherein the planarization coat (10) is a coat formed by deposition, in particular chemical vapor deposition, preferably low-pressure chemical vapor deposition and/or plasma-assisted chemical vapor deposition, and/or by physical vapor deposition and/or atomic layer deposition of at least one coating material on the side (9) of the wafer (1) facing away from the front-end-of-line (5) and preferably subsequent processing of the deposited material on the side (11) facing away from the wafer (1) by means of chemical-mechanical polishing and/or by means of resist planarization,
and/or
wherein the planarization coat (10) is characterized on its side (11) facing away from the wafer (1) by a roughness of less than 2.0 nm RMS, preferably less than 1.0 nm RMS, particularly preferably less than 0.3 nm RMS,
and/or
wherein the planarization coat (10) comprises or consists of spin-on-glass and/or at least one polymer and/or at least one oxide, in particular silicon dioxide, and/or at least one nitride.

6. Semiconductor device according to claim 3, wherein the photonic platform (8) comprises at least one further planarization coat (13), the further planarization coat (13) or at least one of the further planarization coats (13) preferably being made of the same material as the planarization coat (10).

7. Semiconductor device according to claim 6, wherein the further planarization coat (13) or at least one of the further planarization coats (13) is formed by deposition, in particular chemical vapor deposition, preferably low-pressure chemical vapor deposition and/or plasma-assisted chemical vapor deposition, and/or by physical vapor deposition and/or atomic layer deposition of at least one coating material on the side (9) of the wafer (1) facing away from the front-end-of-line (5) and preferably subsequent processing of the deposited material on the side (14) facing away from the wafer (1) by means of chemical-mechanical polishing and/or by means of resist planarization,
and/or
wherein the further planarization coat (13) or at least one of the further planarization coats (13) is characterized on its side (14) facing away from the wafer (1) by a roughness of less than 2.0 nm RMS, preferably less than 1.0 nm RMS, particularly preferably less than 0.3 nm RMS,
and/or
wherein the further planarization coat (13) or at least one of the further planarization coats (13) comprises or consists of spin-on-glass and/or at least one polymer and/or at least one oxide, in particular silicon dioxide, and/or at least one nitride.

8. Semiconductor device according to claim 1, wherein the at least one waveguide (12) comprises or consists of titanium dioxide and/or aluminium nitride and/or tantalum pentoxide and/or silicon nitride and/or aluminium oxide and/or silicon oxynitride and/or lithium niobate and/or silicon, in particular polysilicon, and/or indium phosphite and/or gallium arsenide and/or indium gallium arsenide and/or aluminium gallium arsenide and/or at least one dichalcogenide, in particular two-dimensional transition metal dichalcogenide, and/or chalcogenide glass and/or resin or resin-containing materials, in particular SU8, and/or polymers or polymer-containing materials, in particular OrmoComp.

9. Semiconductor device according to claim 1, wherein the photonic platform (8) comprises a plurality of waveguides (12), preferably at least two waveguides (12) extending at least in sections one above the other.

10. Semiconductor device according to claim 1, wherein the semiconductor device, in particular the photonic platform (8) comprises at least one coupling device (20) associated with at least one of the waveguides (12), the at least one coupling device (32) preferably serving to couple electromagnetic radiation into the at least one associated waveguide (12), and/or to couple electromagnetic radiation out of the at least one associated waveguide (12).

11. Semiconductor device according to claim 1, wherein the electro-optical device (15) or at least one of the electro-optical devices (15) comprises at least one active element (16, 16a, 16b) comprising or consisting of at least one material, which absorbs electromagnetic radiation of at least one wavelength and generates an electrical photosignal as a result of the absorption and/or whose refractive index changes as a function of a voltage and/or the presence of a charge and/or an electric field.

12. Semiconductor device according to claim 11, wherein the electro-optical device (15) or at least one of the electro-optical devices is provided by a modulator (15) comprising an active element (16a) having or consisting of at least one material, whose refractive index changes as a function of a voltage and/or the presence of charge and/or an electric field, in particular graphene and/or at least one dichalcogenide, in particular two-dimensional transition dichalcogenide, and/or heterostructures of two-dimensional materials and/or germanium and/or lithium niobate and/or at least one electro-optical polymer and/or silicon and/or at least one compound semiconductor, in particular at least one III-V semiconductor and/or at least one II-VI semiconductor,
and a further active element (16b) comprising or consisting of at least one material, whose refractive index changes as a function of a voltage and/or the presence of charge and/or an electric field, in particular graphene and/or at least one dichalcogenide, in particular two-dimensional transition dichalcogenide, and/or heterostructures of two-dimensional materials and/or germanium and/or lithium niobate and/or at least one electro-optical polymer and/or silicon and/or at least one compound semiconductor, in particular at least one III-V semiconductor and/or at least one II-VI semiconductor, or an electrode,
wherein the two active elements (16a, 16b) or the active element and the electrode are preferably spaced apart from one another and/or are arranged offset from one another in such a way that they lie one above the other in sections.

13. Semiconductor device according to claim 1, wherein the electro-optical device (15) or at least one of the electro-optical devices is given by a photodetector (15) comprising one, preferably exactly one active element (16) consisting of or comprising at least one material which absorbs electromagnetic radiation of at least one wavelength and generates an electrical photosignal as a result of the absorption, in particular graphene and/or at least one dichalcogenide, in particular two-dimensional transition dichalcogenide, and/or heterostructures of two-dimensional materials and/or germanium and/or silicon and/or at least one compound semiconductor, in particular at least one III-V semiconductor and/or at least one II-VI semiconductor.

14. Semiconductor device according to claim 11, wherein, on or above the active element or at least one of the active elements (16, 16a, 16b), at least one plasmonic structure (29) consisting of or comprising a plasmonically active material, preferably gold and/or silver and/or aluminium and/or copper, is provided, the plasmonic structure (29) preferably comprising at least one pair of plasmonic elements (30) arranged next to one another and consisting of or comprising the plasmonically active material, which plasmonic elements (30) are preferably characterized by a section tapering in the direction of the respective other plasmonic element (30).

15. Semiconductor device according to claim 13, wherein on at least one side of the active element or at least one active element (16, 16a, 16b) a waveguide (12) is provided with an end section (31) tapering in the direction of the active element and preferably ending in a tip, wherein the tapering end section (31) preferably extends up to the active element or the at least one active element (16, 16a, 16b), and/or wherein a contact element (19) is provided on each of two sides of the tapering section (31), which contact element (19) is connected to the active element or the at least one active element (16, 16a, 16b) and which contact element (19) has a section (19a) tapering in the opposite direction and lying next to the ta-pering end section (31) of the waveguide (12).

16. Semiconductor device according to claim 15, wherein a wave-guide (12) having an end section (31) tapering in the direction of the active element or the at least one active element (16, 16a, 16b) and preferably ending in a tip is provided on two sides of the active element or the at least one active element (16, 16a, 16b) in each case, wherein the respective tapering end section (31) preferably extends as far as the active element or the at least one active element (16, 16a, 16b), and/or wherein a contact element (19) is provided on each of two sides of the respective tapering section (31), which contact element (19) is connected to the active element or the at least one active element (16, 16a, 16b) and which contact element (19) has a section (19a) tapering in the opposite direction and lying next to the tapering end section (31) of the respective waveguide (12).

17. Method of manufacturing a semiconductor device, comprising the steps:
a wafer (1) having a preferably single-piece semiconductor substrate (2), in particular silicon substrate, and at least one integrated electronic component (3) extending in and/or on the semiconductor substrate (2) is provided, the wafer (1) having a front-end-of-line (5) and a back-end-of-line (6) lying there above, wherein the front-end-of-line (5) comprises the integrated electronic component (3) or at least one of the integrated electronic components (3),
a photonic platform (8) is fabricated on the side (9) of the wafer (1) facing away from the front-end-of-line (5), the photonic platform (8) comprising at least one waveguide (12) and at least one electro-optical device (15), in particular at least one photodetector and/or at least one electro-optical modulator.

18. Method according to claim 17, wherein the back-end-of-line (6) of the provided wafer (1) comprises interconnection elements (7) connected to the integrated electronic component (3) or at least one of the integrated electronic components (3) of the front-end-of-line (5) and, in the photonic platform (8), inter-connection elements (7) are fabricated which are connected, on the one hand, to the interconnection elements (7) of the back-end-of-line (6) and, on the other hand, to the electro-optical device (15) or at least one of the electro-optical devices (15).

19. Method according to claim 17, wherein the fabrication of the photonic platform (8) includes depositing material on the side (9) of the wafer (1) facing away from the front-end-of-line (5).

20. Method according to claim 17, wherein the fabrication of the photonic platform (8) includes fabricating a planarization coat (10) of a dielectric material in particular on the side (9) of the wafer (1) facing away from the front-end-of-line (5), and preferably the or at least one of the waveguides (12) is fabricated on the side (11) of the planarization coat (10) facing away from the wafer (1).

21. Method according to claim 20, wherein the fabrication of the planarization coat (10) includes that a coating material is applied, in particular deposited, to the side (9) of the wafer (1) and the coating material is at least on its side (11) facing away from the wafer (1) subsequently subjected to a planarization treatment, in particular chemically-mechanically polishing and/or resist-planarization, preferably in such a way that a roughness of the side of less than 2.0 nm, preferably less than 1.0 nm RMS, particularly preferably less than 0.3 nm RMS is obtained.

22. Method according to claim 20, wherein at least one further planarization coat (13) is preferably fabricated following the fabrication of the at least one waveguide (12), the fabrication of the further planarization coat (13) preferably including that a coating material is applied, in particular deposited, to the side (11) of the planarization coat (10) facing away from the wafer (1) and/or of the at least one waveguide (12) and the coating material is then, at least on its side (14) facing away from the wafer (1), subjected to a planarization treatment, in particular chemical-mechanical polishing and/or resist planarization, preferably in such a way that a roughness of the side of less than 2.0 nm, preferably less than 1.0 nm RMS, particularly preferably less than 0.3 nm RMS is obtained.

23. Method according to claim 20, wherein the fabrication of the planarization coat (10) and/or the further planarization coat (13) includes applying a further coating material to the treated side following the planarization treatment.

24. Method according to claim 20, wherein the fabrication of the at least one waveguide (12) includes applying a waveguide material in particular to the side (11) of the planarization coat (10) facing away from the wafer (5), preferably depositing or spinning or transferring it thereon, and then preferably carrying out a structuring of the applied waveguide material in particular by means of lithography and/or reactive ion etching.

25. Method according to claim 17, wherein the or at least one waveguide (12) at least one coupling device (32) is manufactured, which serves for coupling electromagnetic radiation into the at least one waveguide (12) and/or for coupling electromagnetic radiation out of the at least one waveguide (12).

26. Method of manufacturing at least one semiconductor apparatus (38), wherein a semiconductor device according to claim 1 is provided and fragmented.

27. A semiconductor apparatus (38) obtained by fragmenting a semiconductor device according to claim 1.
